(19) United States
(12) Patent Application Publication
(10) Pub. No.: US 2025/0071037 A1
(43) Pub. Date: Feb. 27, 2025

(54) MANAGEMENT OF DATA TRANSFER FOR NETWORK OPERATION

(71) Applicant: Intel Corporation, Santa Clara, CA (US)

(72) Inventors: Daniel Biederman, Saratoga, CA (US); Patrick Connor, Beaverton, OR (US); Karthik Kumar, Chandler, AZ (US); Marcos Carranza, Portland, OR (US); Anjali Singhai Jain, Portland, OR (US)

(73) Assignee: Intel Corporation, Santa Clara, CA (US)

(21) Appl. No.: 18/947,112

(22) Filed: Nov. 14, 2024

(51) Int. Cl. H04L 43/0823; G11C 7/10

(52) U.S. Cl. CPC H04L 43/0847; G11C 7/1006

(57) ABSTRACT

Management of data transfer for network operation is described. An example of an apparatus includes one or more network interfaces and a circuitry for management of data transfer for a network, wherein the circuitry for management of data transfer includes at least circuitry to analyze a plurality of data elements transferred on the network to identify data elements that are delayed or missing in transmission on the network, circuitry to determine one or more responses to delayed or missing data on the network, and circuitry to implement one or more data modifications for delayed or missing data on the network, including circuitry to provide replacement data for the delayed or missing data on the network.

### BACKGROUND OF THE DISCLOSURE

Artificial intelligence (AI) processing is extremely data intensive, as well as being sensitive to latency in processing. The processing that is required for AI processing involves many parallel data calculations that are directed to software.

However, the parallel processes may include a number of calculations that are slow in operations for many reasons, and thus are not available when other calculations are completed. The nature of AI processing means that these delays can have a great impact in the overall speed of processing.

### BRIEF DESCRIPTION OF THE DRAWINGS

Embodiments described herein are illustrated by way of example and not limitation in the figures of the accompanying drawings in which like references indicate similar elements, and in which:

FIG. 1 is a block diagram illustrating a computer system configured to implement one or

more aspects of the embodiments described herein;

FIG. 2 is a block diagram of a system that includes selected components of a datacenter;

FIG. 3 is a block diagram of a portion of a datacenter, according to one or more examples of the present specification;

FIG. 4A-4C illustrates programmable forwarding elements and adaptive routing;

FIG. 5A-5B depicts example network interface devices;

FIG. 6 is a block diagram illustrating a programmable network interface and data processing unit;

FIG. 7 is a block diagram illustrating an IP core development system;

FIG. 8 is an illustration of network processing for a model;

FIG. 9 is an illustration of last packet processing in an apparatus, according to some embodiments;

FIG. 10 is an illustration of a computing system or apparatus including support for concurrent processing and data movement in a data pipeline, according to some embodiments;

FIG. 11A is an illustration of a hardware accelerator including circuitry for concurrent processing and data movement for pipeline operation, according to some embodiments;

FIG. 11B is an illustration of logged data for models and senders generated by a hardware accelerator, according to some embodiments; and

FIG. 12 is a flowchart to illustrate a process for data management in pipeline operation, according to some embodiments.

### DETAILED DESCRIPTION

In some embodiments, an apparatus, system, or process includes management of data transfer for network operation.

In the following description, numerous specific details are set forth to provide a more thorough understanding. However, it will be apparent to one of skill in the art that the embodiments described herein may be practiced without one or more of these specific details. In other instances, well-known features have not been described to avoid obscuring the details of the present embodiments.

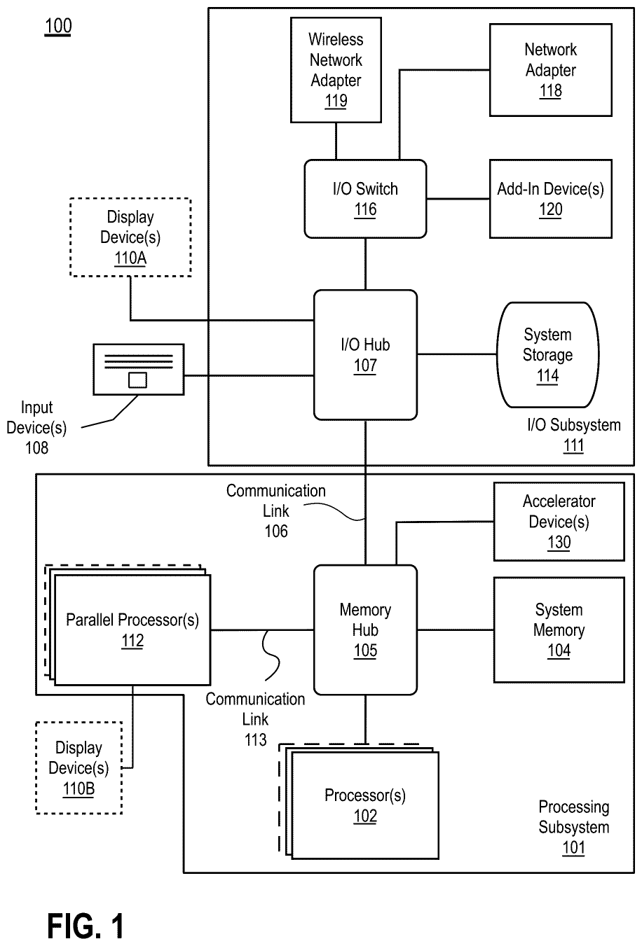

FIG. 1 is a block diagram illustrating a computing system 100 configured to implement one or more aspects of the embodiments described herein. The computing system 100 includes a processing subsystem 101 having one or more processor(s) 102, such as central processing units (CPUs) or other host processors, and a system memory 104, which may communicate via an interconnection path that may include a memory hub 105. The memory hub 105 may be a separate component within a chipset component or may be integrated within the one or more processor(s) 102. The memory hub 105 couples with an I/O subsystem 111 via a communication link 106. The I/O subsystem 111 includes an I/O hub 107 that can enable the computing system 100 to receive input from one or more input device(s) 108. Additionally, the I/O hub 107 can enable a display controller, which may be included in the one or more processor(s) 102, to provide outputs to one or more display device(s) 110A. In one embodiment the one or more display device(s) 110A coupled with the I/O hub 107 can include a local, internal, or embedded display device.

The processing subsystem 101, for example, includes one or more parallel processor(s) 112 coupled to memory hub 105 via a communication link 113, such as a bus or fabric. The communication link 113 may be one of any number of standards-based communication link technologies or protocols, such as, but not limited to PCI Express, or may be a vendor specific communications interface or communications fabric. The one or more parallel processor(s) 112 may form a computationally focused parallel or vector processing system that can include a large number of processing cores and/or processing clusters, such as a many integrated core (MIC) processor. For example, the one or more parallel processor(s) 112 form a graphics processing subsystem that can output pixels to one of the one or more display device(s) 110A coupled via the I/O hub 107. The one or more parallel processor(s) 112 can also include a display controller and display interface (not shown) to enable a direct connection to one or more display device(s) 110B.

Within the I/O subsystem 111, a system storage unit 114 can connect to the I/O hub 107 to provide a storage mechanism for the computing system 100. An I/O switch 116 can be used to provide an interface mechanism to enable connections between the I/O hub 107 and other components, such as a network adapter 118 and/or wireless network adapter 119 that may be integrated into the platform, and various other devices that can be added via one or more add-in device(s) 120. The add-in device(s) 120 may also include, for example, one or more external graphics processor devices, graphics cards, and/or compute accelerators. The network adapter 118 can be an Ethernet adapter or another wired network adapter. The wireless network adapter 119 can include one or more of a Wi-Fi, Bluetooth, near field communication (NFC), or other network device that includes one or more wireless radios.

The computing system 100 can include other components not explicitly shown, including USB or other port connections, optical storage drives, video capture devices, and the like, which may also be connected to the I/O hub 107. Communication paths interconnecting the various components in FIG. 1 may be implemented using any suitable protocols, such as PCI (Peripheral Component Interconnect) based protocols (e.g., PCI-Express), or any other bus or point-to-point communication interfaces and/or protocol(s), such as the NVLink high-speed interconnect, Compute Express Link™ (CXL™) (e.g., CXL.mem), Infinity Fabric (IF), Ethernet (IEEE 802.3), remote direct memory access (RDMA), InfiniBand, Internet Wide Area RDMA Protocol (iWARP), Transmission Control Protocol (TCP), Internet Protocol (IP), User Datagram Protocol (UDP), quick UDP Internet Connections (QUIC), RDMA over Converged Ethernet (RoCE), Ultra Ethernet Transport (UET), Intel QuickPath Interconnect (QPI), Intel Ultra Path Interconnect (UPI), Intel On-Chip System Fabric (IOSF), Omnipath, HyperTransport, Advanced Microcontroller Bus Architecture (AMBA) interconnect, Open Coherent Accelerator Processor Interface (CAPI), Gen-Z, Cache Coherent Interconnect for Accelerators (CCIX), 3rd Generation Partnership Projects (3GPP) Long Term Evolution (LTE) (e.g., 4th generation (4G)), 3GPP 5th generation (5G), and variations thereof, or wired or wireless interconnect protocols known in the art. In some examples, data can be copied or stored to virtualized storage nodes using a protocol such as non-volatile memory express (NVMe) over Fabrics (NVMe-oF) or NVMe. In one embodiment, time-aware communication protocols are supported, including time-aware RDMA, time-aware NVME, and time-aware NVME-oF, in which a precise time and rate of data consumption is used to control the transfer of data.

The one or more parallel processor(s) 112 may incorporate circuitry optimized for graphics and video processing, including, for example, video output circuitry, and constitutes a graphics processing unit (GPU). Alternatively or additionally, the one or more parallel processor(s) 112 can incorporate circuitry optimized for general purpose processing, while preserving the underlying computational architecture, described in greater detail herein. Components of the computing system 100 may be integrated with one or more other system elements on a single integrated circuit. For example, the one or more parallel processor(s) 112, memory hub 105, processor(s) 102, and I/O hub 107 can be integrated into a system on chip (SoC) integrated circuit. Alternatively, the components of the computing system 100 can be integrated into a single package to form a system in package (SiP) configuration. In one embodiment at least a portion of the components of the computing system 100 can be integrated into a multi-chip module (MCM), which can be interconnected with other multi-chip modules into a modular computing system.

In some configurations, the computing system 100 includes one or more accelerator device(s) 130 coupled with the memory hub 105, in addition to the processor(s) 102 and the one or more parallel processor(s) 112. The accelerator device(s) 130 are configured to perform domain specific acceleration of workloads to handle tasks that are computationally intensive or require high throughput. The accelerator device(s) 130 can reduce the burden placed on the processor(s) 102 and/or parallel processor(s) 112 of the computing system 100. The accelerator device(s) 130 can include but are not limited to smart network interface cards, infrastructure processing units (IPUs), data processing units (DPUs), cryptographic accelerators, storage accelerators, artificial intelligence (AI) accelerators, neural processing units (NPUs), storage accelerators, and/or video transcoding accelerators.

In some embodiments, the accelerator device(s) 130 include data management circuitry to support concurrent processing and data movement for pipeline operation, wherein data management circuitry may include analysis circuitry to analyze a plurality of data elements transferred on the network to identify data elements that are delayed or missing in transmission on the network, determination circuitry to determine one or more responses to delayed or missing data on the network, and data modification circuitry to implement one or more data modifications for delayed or missing data on the network, wherein the data modification may include one or more of multiple different types of data modifications, wherein the data modification circuitry may include circuitry to provide replacement data for the delayed or missing data on the network.

It will be appreciated that the computing system 100 shown herein is illustrative and that variations and modifications are possible. The connection topology, including the number and arrangement of bridges, the number of processor(s) 102, and the number of parallel processor(s) 112, may be modified as desired. For instance, system memory 104 can be connected to the processor(s) 102 directly rather than through a bridge, while other devices communicate with system memory 104 via the memory hub 105 and the processor(s) 102. In other alternative topologies, the parallel processor(s) 112 are connected to the I/O hub 107 or directly to one of the one or more processor(s) 102, rather than to the memory hub 105. In other embodiments, the I/O hub 107 and memory hub 105 may be integrated into a single chip. It is also possible that two or more sets of processor(s) 102 are attached via multiple sockets, which can couple with two or more instances of the parallel processor(s) 112.

Some of the particular components shown herein are optional and may not be included in all implementations of the computing system 100. For example, any number of add-in cards or peripherals may be supported, or some components may be eliminated. Furthermore, some architectures may use different terminology for components similar to those illustrated in FIG. 1.

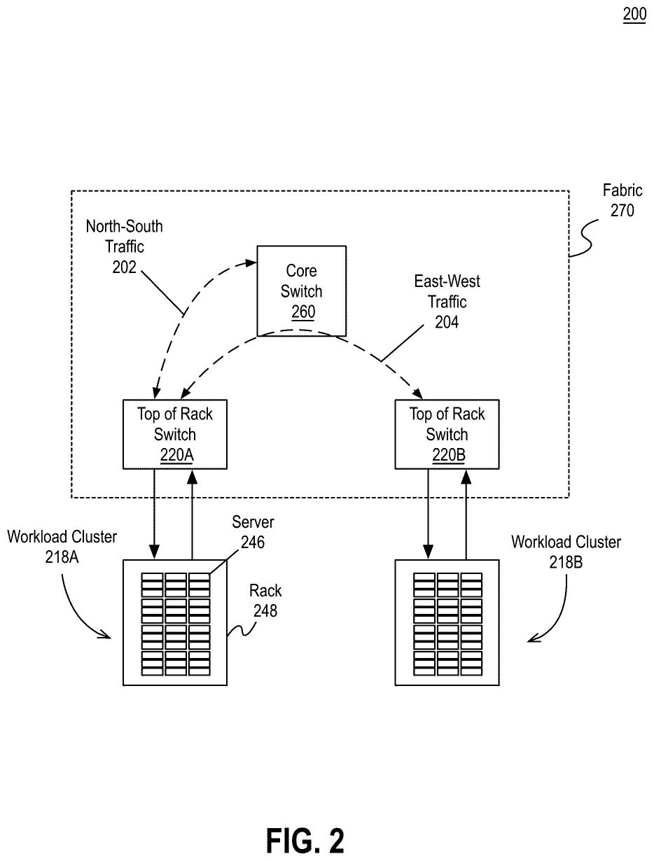

FIG. 2 is a block diagram of a system 200 that includes selected components of a datacenter. The components of the illustrated datacenter may reside, for example within a cloud service provider (CSP), or another datacenter, which may be, by way of nonlimiting example, a traditional enterprise datacenter, an enterprise “private cloud,” or a “public cloud,” providing services such as infrastructure as a service (IaaS), platform as a service (PaaS), or software as a service (SaaS). The system 200 includes some number of workload clusters, including but not limited to workload cluster 218A and workload cluster 218B. The workload clusters may be clusters of individual servers, blade servers, rackmount servers, or any other suitable server topology.

The system 200 may include workload clusters 218A-218B. The workload clusters 218A-218B can include a rack 248 that houses multiple servers (e.g., server 246). The rack 248 and the servers of the workload clusters 218A-218B may conform to the rack unit (“U”) standard, in which one rack unit conforms to a 19 inch wide rack frame and a full-sized industry standard rack accommodates 42 units (42 U) of equipment. One unit (1 U) of equipment (e.g., a 1 U server) may be 1.75 inches high and approximately 36 inches deep. In various configurations, compute resources such as processors, memory, storage, accelerators, and switches may fit into some multiple of rack units within a rack 248.

A server 246 may host a standalone operating system configured to provide server functions, or the servers may be virtualized. A virtualized server may be under the control of a virtual machine manager (VMM), hypervisor, and/or orchestrator, and may host one or more virtual machines, virtual servers, or virtual appliances. The workload clusters 218A-218B may be collocated in a single datacenter, or may be located in different geographic datacenters. Depending on the contractual agreements, some servers may be specifically dedicated to certain enterprise clients or tenants while other servers may be shared.

The various devices in a datacenter may be interconnected via a switching fabric 270, which may include one or more high speed routing and/or switching devices. The switching fabric 270 may provide north-south traffic 202 (e.g., traffic to and from the wide area network (WAN), such as the internet), and east-west traffic 204 (e.g., traffic across the datacenter). Historically, north-south traffic 202 accounted for the bulk of network traffic, but as web services become more complex and distributed, the volume of east-west traffic 204 has risen. In many datacenters, cast-west traffic 204 now accounts for the majority of traffic. Furthermore, as the capability of a server 246 increases, traffic volume may further increase. For example, a server 246 may provide multiple processor slots, with a slot accommodating a processor having four to eight cores, along with sufficient memory for the cores. Thus, a server may host a number of VMs that may be a source of traffic generation.

To accommodate the large volume of traffic in a datacenter, a highly capable implementation of the switching fabric 270 may be provided. The illustrated implementation of the switching fabric 270 is an example of a flat network in which a server 246 may have a direct connection to a top-of-rack switch (ToR switch 220A-220B) (e.g., a “star” configuration). ToR switch 220A can connect with a workload cluster 218A, while ToR switch 220B can connect with workload cluster 218B. A ToR switch 220A-220B may couple to a core switch 260. This two-tier flat network architecture is shown only as an illustrative example and other architectures may be used, such as three-tier star or leaf-spine (also called “fat tree” topologies) based on the “Clos” architecture, hub-and-spoke topologies, mesh topologies, ring topologies, or 3-D mesh topologies, by way of nonlimiting example.

The switching fabric 270 may be provided by any suitable interconnect using any suitable interconnect protocol. For example, a server 246 may include a fabric interface (FI) of some type, a network interface card (NIC), or other host interface. The host interface itself may couple to one or more processors via an interconnect or bus, such as PCI, PCIe, or similar, and in some cases, this interconnect bus may be considered to be part of the switching fabric 270. The switching fabric may also use PCIe physical interconnects to implement more advanced protocols, such as compute express link (CXL).

The interconnect technology may be provided by a single interconnect or a hybrid interconnect, such as where PCIe provides on-chip communication, 1 Gb or 10 Gb copper Ethernet provides relatively short connections to a ToR switch 220A-220B, and optical cabling provides relatively longer connections to core switch 260. Interconnect technologies include, by way of nonlimiting example, Ultra Path Interconnect (UPI), FibreChannel, Ethernet, FibreChannel over Ethernet (FCoE), InfiniBand, PCIe, NVLink, or fiber optics, to name just a few. Some of these will be more suitable for certain deployments or functions than others, and selecting an appropriate fabric for the instant application is an exercise of ordinary skill.

In one embodiment, the switching elements of the switching fabric 270 are configured to implement switching techniques to improve the performance of the network in high usage scenarios. Exemplary advanced switching techniques include but are not limited to adaptive routing, adaptive fault recovery, and adaptive and/or telemetry-based congestion control.

Adaptive routing enables a ToR 220A-220B switch and/or core switch 260 to select the output port to which traffic is switched based on the load on the selected port, assuming unconstrained port selection is enabled. An adaptive routing table can configure the forwarding tables of switches of the switching fabric 270 to select between multiple ports between switches when multiple connections are present between a given set of switches in an adaptive routing group. Adaptive fault recovery (e.g., self-healing) enables the automatic selection of an alternate port if the ported selected by the forwarding table port is in a failed or inactive state, which enables rapid recovery in the event of a switch-to-switch port failure. A notification can be sent to neighboring switches when adaptive routing or adaptive fault recovery becomes active in a given switch. Adaptive congestion control configures a switch to send a notification to neighboring switches when port congestion on that switch exceeds a configured threshold, which may cause those neighboring switches to adaptively switch to uncongested ports on that switch or switches associated with an alternate route to the destination.

Telemetry-based congestion control uses real-time monitoring of telemetry from network devices, such as switches within the switching fabric 270, to detect when congestion will begin to impact the performance of the switching fabric 270 and proactively adjust the switching tables within the network devices to prevent or mitigate the impending congestion. A ToR 220A-220B switch and/or core switch 260 can implement a built-in telemetry-based congestion control algorithm or can provide an application programming interface (API) though which a programmable telemetry-based congestion control algorithm can be implemented. A continuous feedback loop may be implemented in which the telemetry-based congestion control system continuously monitors the network and adjusts the traffic flow in real-time based on ongoing telemetry data. Learning and adaptation can be implemented by the telemetry-based congestion control system in which the system can adapt to changing network conditions and improve its congestion control strategies based on historical data and trends.

Note however that while high-end fabrics are provided herein by way of illustration, more generally, the switching fabric 270 may include any suitable interconnect or bus for the particular application, including legacy interconnects used to implement a local area network (LANs), synchronous optical networks (SONET), asynchronous transfer mode (ATM) networks, wireless networks such as Wi-Fi and Bluetooth, 4G wireless, 5G wireless, digital subscriber line (DSL) interconnects, multimedia over coax alliance (MoCA) interconnects, or similar wired or wireless networks. It is also expressly anticipated that in the future, new network technologies will arise to supplement or replace some of those listed here, and any such future network topologies and technologies can be or form a part of the switching fabric 270.

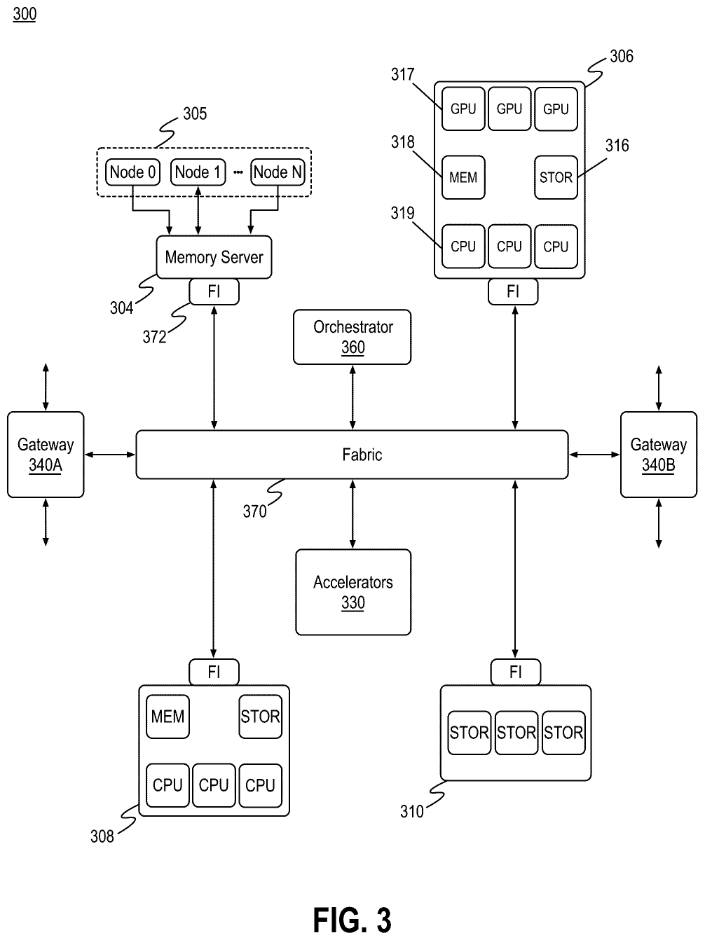

FIG. 3 is a block diagram of a portion of a datacenter 300, according to one or more examples of the present specification. The illustrated portion of the datacenter 300 is not intended to include all components of a datacenter. The illustrated portion may be duplicated multiple times within the datacenter 300 and/or the datacenter 300 may include portions beyond the illustrated portions, depending on the capacity and functionality intended to be provided by the datacenter 300. The datacenter 300 may be, in various embodiments include components of the datacenter of the system 200 of FIG. 2, or may be a different datacenter.

The datacenter 300 includes a number of logic elements forming a plurality of nodes, where a node may be provided by a physical server, a group of servers, or other hardware. A server may also host one or more virtual machines, as appropriate to its application. A fabric 370 is provided to interconnect various aspects of datacenter 300. The fabric 370 may be provided by any suitable interconnect technology, including but not limited to InfiniBand, Ethernet, PCIe, or CXL. The fabric 370 of the datacenter 300 may be a version of and/or include elements of the switching fabric 270 of the system 200 of FIG. 2. The fabric 370 of datacenter 300 can interconnect datacenter elements that include server nodes (e.g., memory server node 304, heterogenous compute server node 306, CPU server node 308, storage server node 310), accelerators 330, gateways 340A-340B to other fabrics, fabric architectures, or interconnect technologies, and an orchestrator 360.

The server nodes of the datacenter 300 can include but are not limited to a memory server node 304, a heterogenous compute server node 306, a CPU server node 308, and a storage server node 310. The heterogenous compute server node 306 and a CPU server node 308 can perform independent operations for different tenants or cooperatively perform operations for a single tenant. The heterogenous compute server node 306 and a CPU server node 308 can also host virtual machines that provide virtual server functionality to tenants of the datacenter.

The server nodes can connect with the fabric 370 via a fabric interface 372. The specific type of fabric interface 372 that is used depends at least in part on the technology or protocol that is used to implement the fabric 370. For example, where the fabric 370 is an Ethernet fabric, the fabric interface 372 may be an Ethernet network interface controller. Where the fabric 370 is a PCIe-based fabric, the fabric interfaces may be PCIe-based interconnects. Where the fabric 370 is an InfiniBand fabric, the fabric interface 372 of the heterogenous compute server node 306 and a CPU server node 308 may be a host channel adapter (HCA), while the fabric interface 372 of the memory server node 304 and storage server node 310 may be a target channel adapter (TCA). TCA functionality may be an implementation-specific subset of HCA functionality. The various fabric interfaces may be implemented as intellectual property (IP) blocks that can be inserted into an integrated circuit as a modular unit, as can other circuitry within the datacenter 300.

The heterogenous compute server node 306 includes multiple CPU sockets that can house a CPU 319, which may be, but is not limited to an Intel® Xeon™ processor including a plurality of cores. The CPU 319 may also be, for example, a multi-core datacenter class ARM® CPU, such as an NVIDIA® Grace™ CPU. The heterogenous compute server node 306 includes memory devices 318 to store data for runtime execution and storage devices 316 to enable the persistent storage of data within non-volatile memory devices. The heterogenous compute server node 306 is enabled to perform heterogenous processing via the presence of GPUs (e.g., GPU 317), which can be used, for example, to perform high-performance compute (HPC), media server, cloud gaming server, and/or machine learning compute operations. In one configuration, the GPUs may be interconnected and CPUs of the heterogenous compute server node 306 via interconnect technologies such as PCIe, CXL, or NVLink.

The CPU server node 308 includes a plurality of CPUs (e.g., CPU 319), memory (e.g., memory devices 318) and storage (storage devices 316) to execute applications and other program code that provide server functionality, such as web servers or other types of functionality that is remotely accessible by clients of the CPU server node 308. The CPU server node 308 can also execute program code that provides services or micro-services that enable complex enterprise functionality. The fabric 370 will be provisioned with sufficient throughput to enable the CPU server node 308 to be simultaneously accessed by a large number of clients, while also retaining sufficient throughput for use by the heterogenous compute server node 306 and to enable the use of the memory server node 304 and the storage server node 310 by the heterogenous compute server node 306 and the CPU server node 308. Furthermore, in one configuration, the CPU server node 308 may rely primarily on distributed services provided by the memory server node 304 and the storage server node 310, as the memory and storage of the CPU server node 308 may not be sufficient for all of the operations intended to be performed by the CPU server node 308. Instead, a large pool of high-speed or specialized memory may be dynamically provisioned between a number of nodes, so that the nodes have access to a large pool of resources, but those resources do not sit idle when that particular node does not need them. A distributed architecture of this type is possible due to the high speeds and low latencies provided by the fabric 370 of contemporary datacenters and may be advantageous because there is no need to over-provision resources for the server nodes.

The memory server node 304 can include memory nodes 305 having memory technologies that are suitable for the storage of data used during the execution of program code by the heterogenous compute server node 306 and the CPU server node 308. The memory nodes 305 can include volatile memory modules, such as DRAM modules, and/or non-volatile memory technologies that can operate similar to DRAM speeds, such that those modules have sufficient throughput and latency performance metrics to be used as a tier of system memory at execution runtime. The memory server node 304 can be linked with the heterogenous compute server node 306 and/or CPU server node 308 via technologies such as CXL.mem, which enables memory access from a host to a device. In such configuration, a CPU 319 of the heterogenous compute server node 306, a CPU server node 308 can link to the memory server node 304 and access the memory nodes 305 of the memory server node 304 in a similar manner as, for example, the CPU 319 of the heterogenous compute server node 306 can access device memory of a GPU within the heterogenous compute server node 306. For example, the memory server node 304 may provide remote direct memory access (RDMA) to the memory nodes 305, in which, for example, the CPU server node 308 may access memory resources on the memory server node 304 via the fabric 370 using direct memory access (DMA) operations, in a similar manner as how the CPU would access its own onboard memory.

The memory server node 304 can be used by the heterogenous compute server node 306 and CPU server node 308 to expand the runtime memory that is available during memory-intensive activities such as the training of machine learning models. A tiered memory system can be enabled in which model data can be swapped into and out of the memory devices 318 of the heterogenous compute server node 306 to memory of the memory server node 304 at higher performance and/or lower latency than local storage (e.g., storage devices 316). During workload execution setup, the entire working set of data may be loaded into one or more of the memory nodes 305 of the memory server node 304 and loaded into the memory devices 318 of the heterogenous compute server node 306 as needed during execution of a heterogenous workload.

The storage server node 310 provides storage functionality to the heterogenous compute server node 306, the CPU server node 308, and potentially the memory server node 304. The storage server node 310 may provide a networked bunch of disks or just a bunch of disks (JBOD), program flash memory (PFM), redundant array of independent disks (RAID), redundant array of independent nodes (RAIN), network attached storage (NAS), or other nonvolatile memory solutions. In one configuration, the storage server node 310 can couple with the heterogenous compute server node 306, the CPU server node 308, and/or the memory server node 304 such as NVMe-oF, which enables the NVME protocol to be implemented over the fabric 370. In such configurations, the fabric interface 372 of those servers may be smart interfaces that include hardware to accelerate NVMe-oF operations.

The accelerators 330 within the datacenter 300 can provide various accelerated functions, including hardware or coprocessor acceleration for functions such as packet processing, encryption, decryption, compression, decompression, network security, or other accelerated functions in the datacenter. In some examples, accelerators 330 may include deep learning accelerators, such as neural processing units (NPU), that can receive offload of matrix multiply operations of other neural network operations from the heterogenous compute server node 306 or the CPU server node 308. In some configurations, the accelerators 330 may reside in a dedicated accelerator server or distributed throughout the various server nodes of the datacenter 300. For example, an NPU may be directly attached to one or more CPU cores within the heterogenous compute server node 306 or the CPU server node 308. In some configurations, the accelerators 330 can include or be included within smart network controllers, infrastructure processing units (IPUs), or data processing units, which combine network controller functionality with accelerator, processor, or coprocessor functionality. The accelerators 330 can also include edge processing units (EPU) to perform real-time inference operations at the edge of the network.

In one configuration, the datacenter 300 can include gateways 340A-340B from the fabric 370 to other fabrics, fabric architectures, or interconnect technologies. For example, where the fabric 370 is an InfiniBand fabric, the gateways 340A-340B may be gateways to an Ethernet fabric. Where the fabric 370 is an Ethernet fabric, the gateways 340A-340B may include routers to route data to other portions of the datacenter 300 or to a larger network, such as the Internet. For example, a first gateway 340A may connect to a different network or subnet within the datacenter 300, while a second gateway 340B may be a router to the Internet.

The orchestrator 360 manages the provisioning, configuration, and operation of network resources within the datacenter 300. The orchestrator 360 may include hardware or software that executes on a dedicated orchestration server. The orchestrator 360 may also be embodied within software that executes, for example, on the CPU server node 308 that configures software defined networking (SDN) functionality of components within the datacenter 300. In various configurations, the orchestrator 360 can enable automated provisioning and configuration of components of the datacenter 300 by performing network resource allocation and template-based deployment. Template-based deployment is a method for provisioning and managing IT resources using predefined templates, where the templates may be based on standard templates required by the government, service provider, financial, standard or customer. The template may also dictate service level agreements (SLA) or service level obligations (SLO). The orchestrator 360 can also perform functionality including but not limited to load balancing and traffic engineering, network segmentation, security automation, real-time telemetry monitoring, and adaptive switching management, including telemetry-based adaptive switching. In some configurations, the orchestrator 360 can also provide multi-tenancy and virtualization support by enabling virtual network management, including the creation and deletion of virtual LANs (VLANs) and virtual private networks (VPNs), and tenant isolation for multi-tenant datacenters.

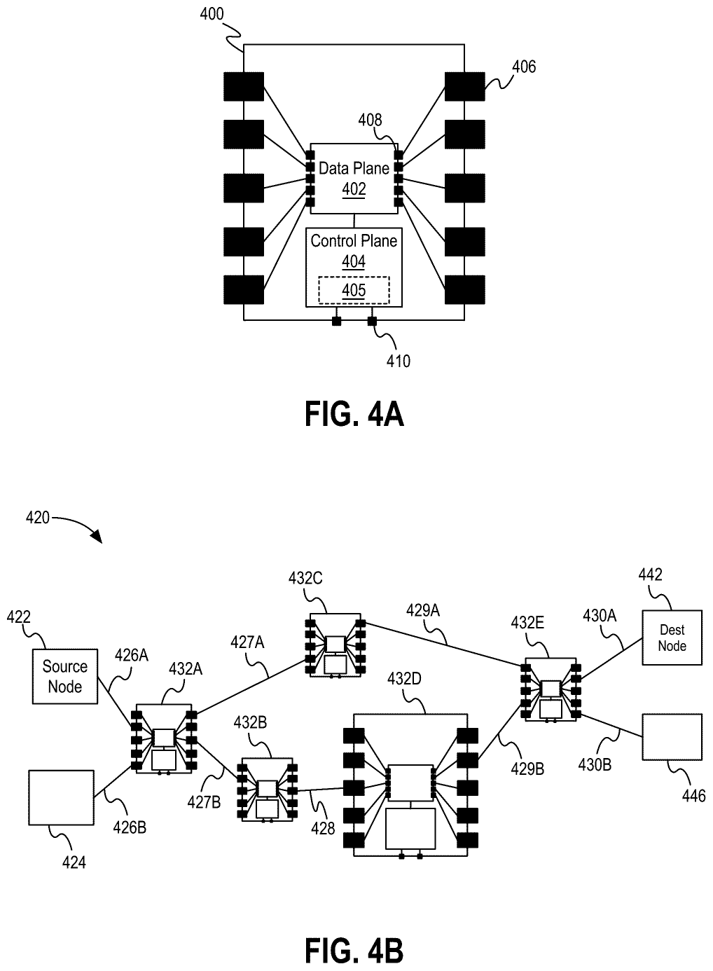

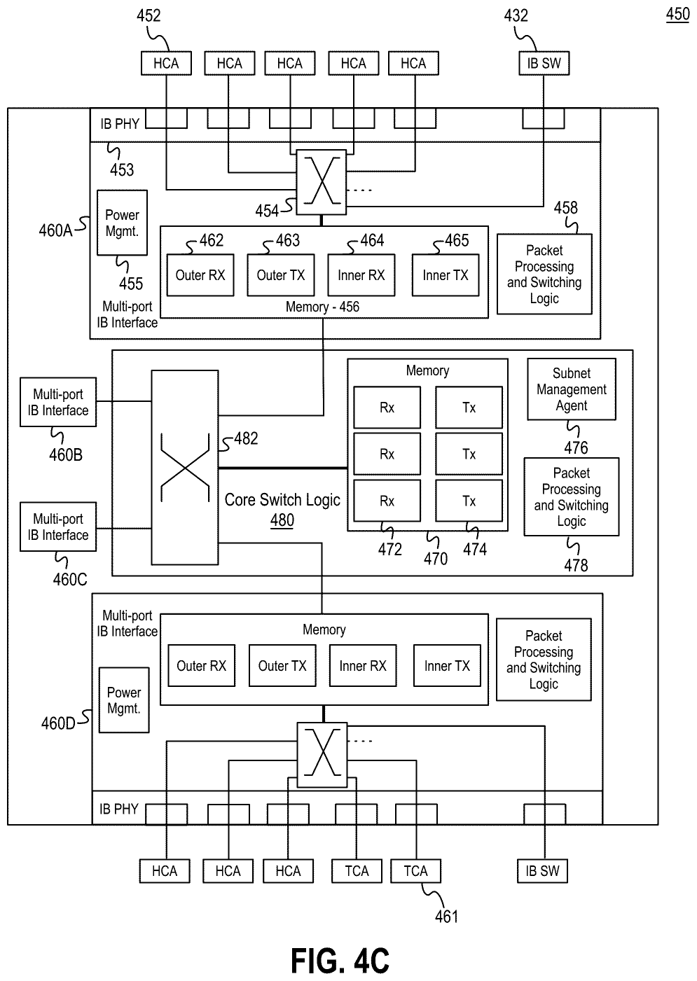

FIG. 4A-4C illustrates programmable forwarding elements and adaptive routing. FIG. 4A illustrates a forwarding element that includes a control plane and a programmable data plane. FIG. 4B illustrates a network having switching devices configured to perform adaptive routing and telemetry-based congestion control. FIG. 4C illustrates an InfiniBand switch including multi-port IB interfaces.

FIG. 4A shows a forwarding element 400 that can be configured to forward data messages within a network based on a program provided by a user. The program, in some embodiments, includes instructions for forwarding data messages, as well as performing other processes such as firewall, denial of service attack protection, and load balancing operations. The forwarding element 400 can be any type of forwarding element, including but not limited to a switch, a router, or a bridge. The forwarding element 400 can forward data messages associated with various technologies, such as but not limited to Ethernet, Ultra Ethernet, InfiniBand, or NVLink.

In various network configurations, the forwarding element is deployed as a non-edge forwarding element in the interior of the network to forward data messages from a source device to a destination device. In network configurations, the forwarding element 400 is deployed as an edge forwarding element at the edge of the network to connect to compute devices (e.g., standalone or host computers) that serve as sources and destinations of the data messages. As a non-edge forwarding element, the forwarding element 400 forwards data messages between forwarding elements in the network, such as through an intervening network fabric. As an edge forwarding element, the forwarding element 400 forwards data messages to and from edge compute devices, to other edge forwarding elements and/or to non-edge forwarding elements.

The forwarding element 400 includes circuitry to implement a data plane 402 that performs the forwarding operations of the forwarding element 400 to forward data messages received by the forwarding element to other devices. The forwarding element 400 also includes circuitry to implement a control plane 404 that configures the data plane circuit. Additionally, the forwarding element 400 includes physical ports 406 that receive data messages from, and transmit data messages to, devices outside of the forwarding element 400. The data plane 402 includes ports 408 that receive data messages from the physical ports 406 for processing. The data messages are processed and forwarded to another port on the data plane 402, which is connected to another physical port of the forwarding element 400. In addition to being associated with physical ports of the forwarding element 400, some of the ports 408 on the data plane 402 may be associated with other modules of the data plane 402.

The data plane includes programmable packet processor circuits that provide several programmable message-processing stages that can be configured to perform the data-plane forwarding operations of the forwarding element 400 to process and forward data messages to their destinations. These message-processing stages perform these forwarding operations by processing data tuples (e.g., message headers) associated with data messages received by the data plane 402 in order to determine how to forward the messages. The message-processing stages include match-action units (MAUs) that try to match data tuples (e.g., header vectors) of messages with table records that specify action to perform on the data tuples. In some embodiments, table records are populated by the control plane 404 and are not known when configuring the data plane to execute a program provided by a network user. The programmable message-processing circuits are grouped into multiple message-processing pipelines. The message-processing pipelines can be ingress or egress pipelines before or after the forwarding element's traffic management stage that directs messages from the ingress pipelines to egress pipelines.

The specifics of the hardware of the data plane 402 depends on the communication protocol implemented via the forwarding element 400. Ethernet switches use application specific integrated circuits (ASICs) designed to handle Ethernet frames and the TCP/IP protocol stack. These ASICs are optimized for a broad range of traffic types, including unicast, multicast, and broadcast. Ethernet switch ASICs are generally designed to balance cost, power consumption, and performance, although high-end Ethernet switches may support more advanced features such as deep packet inspection and advanced QoS (Quality of Service). InfiniBand switches use specialized ASICs designed for ultra-low latency and high throughput. These ASICs enable features such as optimized for handling the InfiniBand protocol and provide support for RDMA and other features that require precise timing and high-speed data processing, although high-end Ethernet switches may support ROCE (RDMA over Converged Ethernet), which offers similar benefits to InfiniBand but with higher latency compared to native InfiniBand RDMA.

The forwarding element 400 may also be configured as an NVLink switch (e.g., NVSwitch), which is used to interconnect multiple graphics processors via the NVLink connection protocol. When configured as an NVLink switch, the forwarding element 400 can provide GPU servers with increased GPU to GPU bandwidth relative to GPU servers interconnected via InfiniBand. An NVLink switch can reduce network traffic hotspots that may occur when interconnected GPU-equipped servers execute operations such as distributed neural network training.

In general, where the data plane 402, in concert with a program executed on the data plane 402 (e.g., a program written in the P4 language), performs message or packet forwarding operations for incoming data, the control plane 404 determines how messages or packets should be forwarded. The behavior of a program executed on the data plane 402 is determined in part by the control plane 404, which populates match-action tables with specific forwarding rules. The forwarding rules that are used by the program executed on the data plane 402 are independent of the data plane program itself. In one configuration, the control plane can couple with a management port 410 that enables administrator configuration of the forwarding element 400. The data connection that is established via the management port 410 is separate from the data connections for ingress and egress data ports. In one configuration, the management ports 410 may connect with a management plane 405, which facilitates administrative access to the device, enables the analysis of device state and health, and enables device reconfiguration. The management plane 405 may be a portion of the control plane 404 or in direct communication with the control plane 404. In one implementation, there is no direct access for the administrator to components of the control plane 404. Instead, information is gathered by the management plane 405 and the changes to the control plane 404 are carried out by the management plane 405.

FIG. 4B shows a network 420 having switches 432A-432E with support for adaptive routing and telemetry-based congestion control. The network 420 can be implemented using a variety of communication protocols described herein. In one embodiment, the network 420 is implemented using the InfiniBand protocol. In one embodiment, the network 420 is an Ethernet, converged Ethernet, or Ultra Ethernet network. The network 420 may include aspects of the fabric 370 of FIG. 3. The switches 432A-432E may be an implementation of the forwarding element 400 of FIG. 4A. The network 420 provides packet-based communication for multiple nodes (e.g., node 424, node 446), including a source node 422 and a destination node 442 of a data transfer to be performed over the network 420. Packets of a flow are forwarded over a route through the network 420 that traverses the switches (switch 432A-432E) and links (link 426A-426B, 427A-427B, 428, 429A-429B, 430A-430B) of the network 420. In an InfiniBand application, the switches and links belong to a certain InfiniBand subnet that is managed by a Subnet Manager (SM), which may be included within one of the switches (e.g., switch 432D). The source node 422 and the destination node 442 are the source and destination nodes for an exemplary dataflow. Depending on the configuration of the network 420, packets may flow from any node to any other node via one or more paths.

The switches 432A-432E include a data plane 402, a control plane 404, a management plane 405, and physical ports 406, as in the forwarding element 400 of FIG. 4A. A processor of the control plane 404 can be used to implement adaptive routing techniques to adjust a route between the source node 422 and the destination node 442 based on the current state of the network. During network operation, the route from the source node 422 to the destination node 442 may at some point become unsuitable or compromised in its ability to transfer packets due to various events, such as congestion, link fault, or head-of-line blocking. Should such scenario occur, the switched 432A-432E can be configured to dynamically adapt the route of the packets that flow along a compromised path.

An adaptive routing (AR) event may be detected by one of the switches along a route that becomes compromised, for example, when the switch when it attempts to output packets on a designated output port. For example, an exemplary data from the source node 422 to the destination node 442 can traverse links through switches of the network. An AR event may be detected by switch 432D for link 429B, for example, in response to congestion or a link fault associated with link 429B. Upon detecting the AR event, switch 432D, as the detecting switch, generates an adaptive routing notification (ARN), which has an identifier that distinguishes an ARN packet from other packet types. In various embodiments, the ARN includes parameters such as an identifier for the detecting switch, the type of AR event, and the source and destination address of the flow that triggered the AR event, and/or any other suitable parameters. The detecting switch sends the ARN backwards along the route to the preceding switches. The ARN may include a request for notified switches to modify the route to avoid traversal of the detected switch. A notified switch can then evaluate whether its routes may be modified to bypass the detecting switch. Otherwise, the switch forwards the ARN to the previous preceding switch along the route. In this scenario, switch 432B is not able to avoid switch 432D and will relay the ARN to switch 432A. Switch 432A can determine to adapt the route to the destination node 442 by using link 427A to switch 432C. Switch 432C can reach switch 432E via link 429A, allowing packets from the source node 422 to reach the destination node 442 while bypassing the AR event related to link 429B.

In various configurations, the network 420 can also adapt to congestion scenarios via programmable data planes within the switches 432A-432E that are able to execute data plane programs to implement in-network congestion control algorithms (CCAs) for TCP over Ethernet-based fabrics. Using in-band network telemetry (INT), programmable data planes within the switches 432A-432E can become aware when a port or link along a route is becoming congested and preemptively seek to route packets over alternate paths. For example, switch 432A can load balance traffic to the destination node 442 between link 427A and link 427B based on the level of congestion seen on the routes downstream from those links.

FIG. 4C shows an InfiniBand switch 450, which may be an implementation of the forwarding element 400 of FIG. 4A. The InfiniBand switch 450 includes a programmable data plane and is configurable to perform adaptive routing and telemetry-based congestion control as described herein. The InfiniBand switch 450 includes multi-port IB interfaces 460A-460D and core switch logic 480. The multi-port IB interfaces 460A-460D include multiple ports. In one embodiment, a single instance of a physical interface (IB PHY 453) is present, with input and output buffers associated with a port. In one embodiment, ports have a separate physical interfaces. The ports can couple with, for example, an HCA 452, a TCA 461, or another InfiniBand switch 432. The multi-port IB interfaces 460A-460D can include a crossbar switch 454 that is configured to selectively couple input and output port buffers to local memory 456. The crossbar switch 454 is a non-blocking crossbar switch that provides direct and low latency switching with a fixed or variable packet size.

The local memory 456 includes multiple queues, including an outer receive queue 462, an outer transmit queue 463, an inner receive queue 464, and an inner transmit queue 465. The outer queues are used for data that is received at a given multi-port IB interface that is to be forwarded back out the same multi-port IB interface. The inner queues are used for data that is forwarded out a different multi-port IB interface than used to receive the data. Other types of queue configurations may be implemented in local memory 456. For example, different queues may be present to support multiple traffic classes, either on an individual port basis, shared port basis, or a combination thereof. The multi-port IB interfaces 460A-460D includes power management circuitry 455, which can adjust a power state of circuitry within the respective multi-port IB interface. Additionally power management logic that performs similar operations may be implemented as part of core switch logic.

The multi-port IB interfaces 460A-460D include packet processing and switching logic 458, which is generally used to perform aspects of packet processing and/or switching operations that are performed at the local multi-port level rather than across the IB switch as a whole. Depending on the implementation, the packet processing and switching logic 458 can be configured to perform a subset of the operations of the packet processing and switching logic 478 within the core switch logic 480, or can be configured with the full functionality of the packet processing and switching logic 478 within the core switch logic 480. The processing functionality of the packet processing and switching logic 458 may vary, depending on the complexity of the operations and/or speed the operations are to be performed. For example, the packet processing and switching logic 458 can include processors ranging from microcontrollers to multi-core processors. A variety of types or architectures of multi-core processors may also be used. Additionally, a portion of the packet processing operations may be implemented by embedded hardware logic.

The core switch logic 480 includes a crossbar 482, memory 470, a subnet management agent (SMA 476), and packet processing and switching logic 478. The crossbar 482 is a non-blocking low latency crossbar that interconnects the multi-port IB interfaces 460A-460D and connects with the memory 470. The memory 470 includes receive queues 472 and transmit queues 474. In one embodiment, packets to be switched between the multi-port IB interfaces 460A-460D can be received by the crossbar 482, stored in one of the receive queues 472, processed by the packet processing and switching logic 478, and stored in a transmit queues 474 for transmission to the outbound multi-port IB interface. In implementations that do not use the multi-port IB interfaces 460A-460D, the core switch logic 480 and crossbar 482 switches packets directly between I/O buffers with the receive queues 472 and transmit queues 474 within the memory 470.

The packet processing and switching logic 478 includes programmable functionality and can execute data plane programs via a variety of types or architectures of multi-core processors. The packet processing and switching logic 478 is representative of the applicable circuitry and logic for implementing switching operations, as well as packet processing operations beyond which may be performed at the ports themselves. Processing elements of the packet processing and switching logic 478 executes software and/or firmware instructions configured to implement packet processing and switch operations. Such software and/or firmware may be stored in non-volatile storage on the switch itself. The software may also be downloaded or updated over a network in conjunction with initializing operations of the InfiniBand switch 450.

The SMA 476 is configurable to manage, monitor, and control functionality of the InfiniBand switch 450. The SMA 476 is also an agent of and in communication of the subnet manager (SM) for the subnet associated with the InfiniBand switch 450. The SM is the entity that discovers the devices within the subnet and performs a periodic sweep of the subnet to detect changes to the subnet's topology. One SMA within a subnet can be elected the primary SMA for the subnet and act as the SM. Other SMAs within the subnet will then communicate with that SMA. Alternatively, the SMA 476 can operate with other SMAs in the subnet to act as a distributed SM. In some embodiments, SMA 476 includes or executes on standalone circuitry and logic, such as a microcontroller, single core processor, or multi-core processor. In other embodiments, SMA 476 is implemented via software and/or firmware instructions executed on a processor core or other processing element that is part of a processor or other processing element used to implement packet processing and switching logic 478.

Embodiments are not specifically limited to implementations including multi-port IB interfaces 460A-460D. In one embodiment, ports are associated with their own receive and transmit buffers, with the crossbar 482 being configured to interconnect those buffers with receive queues 472 and transmit queues 474 in the memory 470. Packet processing and switching is then primarily performed by the packet processing and switching logic 478 of the core switch logic 480.

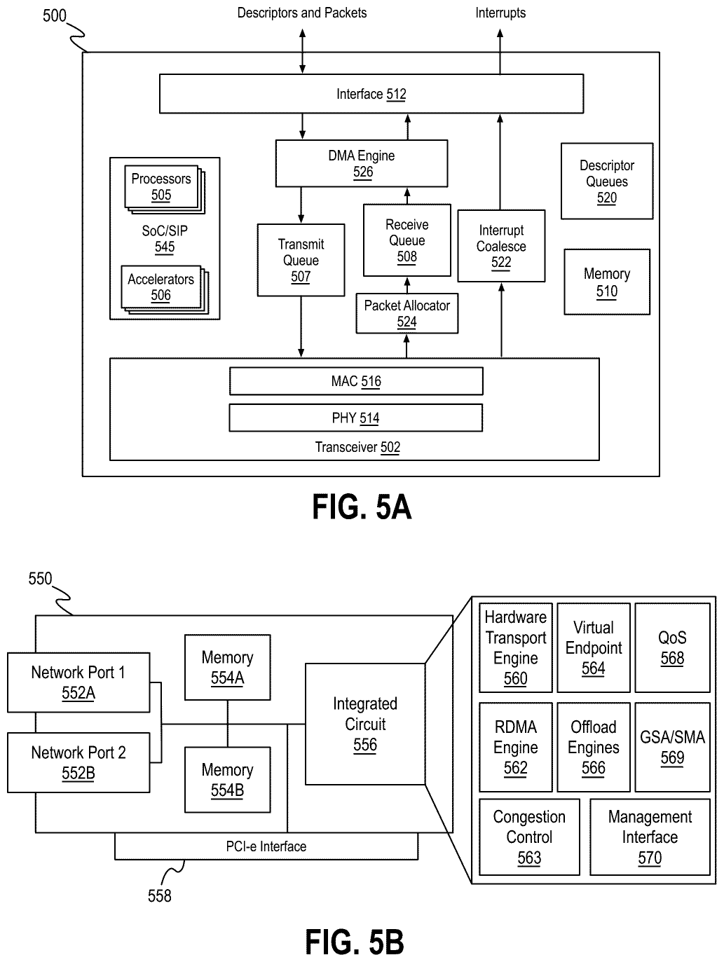

FIG. 5A-5B depict example network interface devices. FIG. 5A illustrates a network interface device 500 that may be configured as a smart Ethernet device. FIG. 5B illustrates a network interface device 550 which may be configured as an InfiniBand channel adapter.

As shown in FIG. 5A, in one configuration, the network interface device 500 can include a transceiver 502, transmit queue 507, receive queue 508, memory 510, and bus interface 512, and DMA engine 526. The network interface device 500 can also include an SoC/SiP 545, which includes processors 505 to implement smart network interface device functionality, as well as accelerators 506 for various accelerated functionality, such as NVMe-oF or RDMA. The specific makeup of the network interface device 500 depends on the protocol implemented via the network interface device 500.

In various configurations, the network interface device 500 is configurable to interface with networks including but not limited to Ethernet, including Ultra Ethernet. However, the network interface device 500 may also be configured as an InfiniBand or NVLink interface via the modification of various components. For example, the transceiver 502 can be capable of receiving and transmitting packets in conformance with the InfiniBand, Ethernet, or NVLink protocols. Other protocols may also be used. The transceiver 502 can receive and transmit packets from and to a network via a network medium. The transceiver 502 can include PHY circuitry 514 and media access control circuitry (MAC circuitry 516). PHY circuitry 514 can include encoding and decoding circuitry to encode and decode data packets according to applicable physical layer specifications or standards. MAC circuitry 516 can be configured to assemble data to be transmitted into packets, that include destination and source addresses along with network control information and error detection hash values.

The SoC/SiP 545 can include processors that may be any a combination of a CPU processor, graphics processing unit (GPU), field programmable gate array (FPGA), application specific integrated circuit (ASIC), or other programmable hardware device that allow programming of network interface device 500. For example, a smart network interface can provide packet processing capabilities in the network interface using processors 505. Configuration of operation of processors 505, including programmable data plane processors, can be programmed using Programming Protocol-independent Packet Processors (P4), C, Python, Broadcom Network Programming Language (NPL), x86, or ARM compatible executable binaries or other executable binaries.

The packet allocator 524 can provide distribution of received packets for processing by multiple CPUs or cores using timeslot allocation. An interrupt coalesce circuit 522 can perform interrupt moderation in which the interrupt coalesce circuit 522 waits for multiple packets to arrive, or for a time-out to expire, before generating an interrupt to host system to process received packet(s). Receive Segment Coalescing (RSC) can be performed by the network interface device 500 in which portions of incoming packets are combined into segments of a packet. The network interface device 500 can then provide this coalesced packet to an application. A DMA engine 526 can copy a packet header, packet payload, and/or descriptor directly from host memory to the network interface or vice versa, instead of copying the packet to an intermediate buffer at the host and then using another copy operation from the intermediate buffer to the destination buffer. The memory 510 can be any type of volatile or non-volatile memory device and can store any queue or instructions used to program the network interface device 500. The transmit queue 507 can include data or references to data for transmission by network interface. The receive queue 508 can include data or references to data that was received by network interface from a network. The descriptor queues 520 can include descriptors that reference data or packets in transmit queue 507 or receive queue 508. The bus interface 512 can provide an interface with host device. For example, the bus interface 512 can be compatible with PCI Express, although other interconnection standards may be used.

As shown in FIG. 5B, a network interface device 550 can be configured as an implementation of the network interface device 500 to implement an InfiniBand HCA. The network interface device 550 includes network ports 552A-552B, memory 554A-554B, a PCIe interface 558 and an integrated circuit 556 that includes hardware, firmware, and/or software to implement, manage, and/or control HCA functionality. In one implementation, the integrated circuit includes a hardware transport engine 560, an RDMA engine 562, congestion control logic 563, virtual endpoint logic 564, offload engines 566, QoS logic 568, GSA/SMA logic 569, and a management interface. Different implementations of the network interface device 550 may include additional components or may exclude some components. A network interface device 550 configured as a TCA will include some implementation specific subset of the functionality of an HCA. The integrated circuit 556 includes programmable and fixed function hardware to implement the described functionality.

While the illustrated implementation of the network interface device 550 is shown as having a PCIe interface 558, other implementations can use other interfaces. For example, the network interface device 550 may use an Open Compute Project (OCP) mezzanine connector. Additionally, the PCIe interface 558 may also be configured with a multi-host solution that enables multiple compute or storage hosts to couple with the network interface device 550. The PCIe interface 558 may also support technology that enables direct PCIe access to multiple CPU sockets, which eliminates the need for network traffic to traverse the inter-processor bus of a multi-socket server motherboard for a server that includes the network interface device 550.

The network interface device 550 implements endpoint elements of the InfiniBand architecture, which is based around queue pairs and RDMA. InfiniBand off-loads traffic control from software through the use of execution queues (e.g., work queues), which are initiated by a software client and managed in hardware. Communication endpoints includes a queue pair (QP) having a send queue and a receive queue. A QP is a memory-based abstraction where communication is achieved between memory-to-memory transfers between applications or between applications and devices. Communication to QPs occurs through virtual lanes of the network ports 552A-552B, which enable multiple independent data flows to share the same link, with separate buffering and flow control for respective flows.

Communication occurs via channel I/O, in which a virtual channel directly connects two applications that exist in separate address spaces. The hardware transport engine 560 includes hardware logic to perform transport level operations via the QP for an endpoint. The RDMA engine 562 leverages the hardware transport engine 560 to perform RDMA operations between endpoints. The RDMA engine 562 implements RDMA operations in hardware and enables an application to read and write the memory of a remote system without OS kernel intervention or unnecessary data copies by allowing one endpoint of a communication channel to place information directly into the memory of another endpoint. The virtual endpoint logic 564 manages the operation of a virtual endpoint for channel I/O, which is a virtual instance of a QP that will be used by an application. The virtual endpoint logic 564 maps the QPs into the virtual address space of an application associated with a virtual endpoint.

Congestion control logic 563 performs operations to mitigate the occurrence of congestion on a channel. In various implementations, the congestion control logic 563 can perform flow control over a channel to limit congestion at the destination of a data transfer. The congestion control logic 563 can perform link level flow control to manage congestion at source congestion at virtual links of the network ports 552A-552B. In some implementations, the congestion control logic can perform operations to limit congestion at intermediate points (e.g., IB switches) along a channel.

Offload engines 566 enable the offload of network tasks that may otherwise be performed in software to the network interface device 550. The offload engines 566 can support offload of operations including but not limited to offload of receive side scaling from a device driver or stateless network operations, for example, for TCP implementations over InfiniBand, such as TCP/UDP/IP stateless offload or Virtual Extensible Local Area Network (VXLAN) offload. The offload engines 566 can also implement operations of a interrupt coalesce circuit 522 of the network interface device 500 of FIG. 5A. The offload engines 566 can also be configured to support offload of NVME-oF or other storage acceleration operations from a CPU.

The QoS logic 568 can perform QoS operations, including QoS functionality that is inherent within the basic service delivery mechanism of InfiniBand. The QoS logic 568 can also implement enhanced InfiniBand QoS, such as fine grained end-to-end QoS. The QoS logic 568 can implement queuing services and management for prioritizing flows and guaranteeing service levels or bandwidth according to flow priority. For example, the QoS logic 568 can configure virtual lane arbitration for virtual lanes of the network ports 552A-552B according to flow priority. The QoS logic 568 can also operate in concert with the congestion control logic 563.

The GSA/SMA logic 569 implements general services agent (GSA) operations to manage the network interface device 550 and the InfiniBand fabric, as well as performing subnet management agent operations. The GSA operations include device-specific management tasks, such as querying device attributes, configuring device settings, and controlling device behavior. The GSA/SMA logic 569 can also implement SMA operations, including a subset of the operations performed by the SMA 476 of the InfiniBand switch 450 of FIG. 4C. For example, the GSA/SMA logic 569 can handle management requests from the subnet manager, including device reset requests, firmware update requests, or requests to modify configuration parameters.

The management interface 570 provides support for a hardware interface to perform out-of-band management of the network interface device 550, such as an interconnect to a board management controller (BMC) or a hardware debug interface.

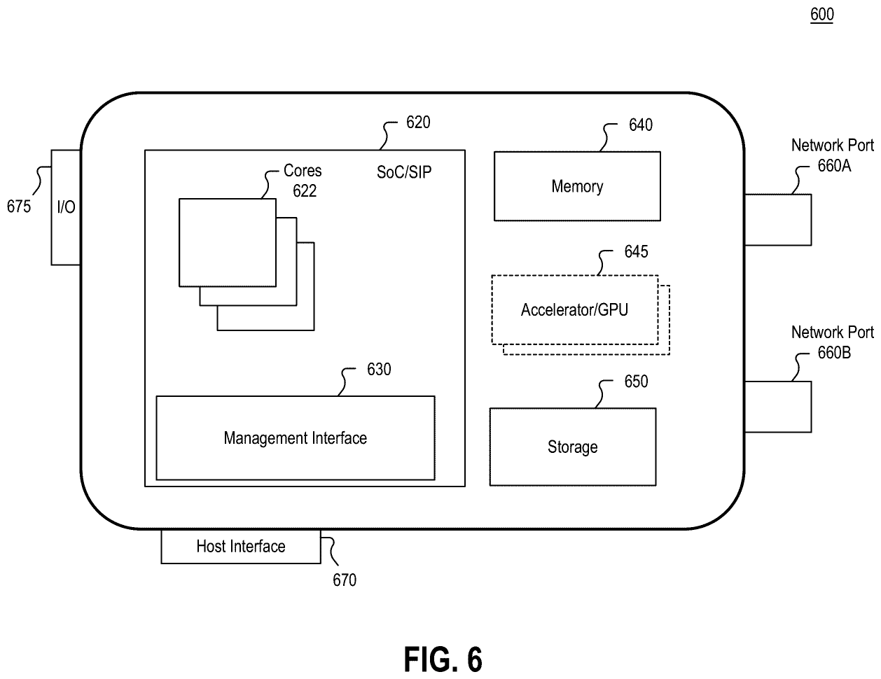

FIG. 6 is a block diagram illustrating a programmable network interface 600 and data processing unit. The programmable network interface 600 is a programmable network engine that can be used to accelerate network-based compute tasks within a distributed environment. The programmable network interface 600 can couple with a host system via host interface 670. The programmable network interface 600 can be used to accelerate network or storage operations for CPUs or GPUs of the host system. The host system can be, for example, a node of a distributed learning system used to perform distributed training, for example, as shown in FIG. 6. The host system can also be a data center node within a data center.

In one embodiment, access to remote storage containing model data can be accelerated by the programmable network interface 600. For example, the programmable network interface 600 can be configured to present remote storage devices as local storage devices to the host system. The programmable network interface 600 can also accelerate RDMA operations performed between GPUs of the host system with GPUs of remote systems. In one embodiment, the programmable network interface 600 can enable storage functionality such as, but not limited to NVME-oF. The programmable network interface 600 can also accelerate encryption, data integrity, compression, and other operations for remote storage on behalf of the host system, allowing remote storage to approach the latencies of storage devices that are directly attached to the host system.

The programmable network interface 600 can also perform resource allocation and management on behalf of the host system. Storage security operations can be offloaded to the programmable network interface 600 and performed in concert with the allocation and management of remote storage resources. Network-based operations to manage access to the remote storage that would otherwise by performed by a processor of the host system can instead be performed by the programmable network interface 600.

In one embodiment, network and/or data security operations can be offloaded from the host system to the programmable network interface 600. Data center security policies for a data center node can be handled by the programmable network interface 600 instead of the processors of the host system. For example, the programmable network interface 600 can detect and mitigate against an attempted network-based attack (e.g., DDoS) on the host system, preventing the attack from compromising the availability of the host system.

The programmable network interface 600 can include a system on a chip (SoC/SiP 620) that executes an operating system via multiple processor cores 622. The processor cores 622 can include general-purpose processor (e.g., CPU) cores. In one embodiment the processor cores 622 can also include one or more GPU cores. The SoC/SiP 620 can execute instructions stored in a memory device 640. A storage device 650 can store local operating system data. The storage device 650 and memory device 640 can also be used to cache remote data for the host system. Network ports 660A-660B enable a connection to a network or fabric and facilitate network access for the SoC/SiP 620 and, via the host interface 670, for the host system. In one configuration, a first network port 660A can connect to a first forwarding element, while a second network port 660B can connect to a second forwarding element. Alternatively, both network ports 660A-660B can be connected to a single forwarding element using a link aggregation protocol (LAG). The programmable network interface 600 can also include an I/O interface 675, such as a Universal Serial Bus (USB) interface. The I/O interface 675 can be used to couple external devices to the programmable network interface 600 or as a debug interface. The programmable network interface 600 also includes a management interface 630 that enables software on the host device to manage and configure the programmable network interface 600 and/or SoC/SiP 620. In one embodiment the programmable network interface 600 may also include one or more accelerators or GPUs 645 to accept offload of parallel compute tasks from the SoC/SiP 620, host system, or remote systems coupled via the network ports 660A-660B. For example, the programmable network interface 600 can be configured with a graphics processor and participate in general-purpose or graphics compute operations in a datacenter environment.

One or more aspects may be implemented by representative code stored on a machine-readable medium which represents and/or defines logic within an integrated circuit such as a processor. For example, the machine-readable medium may include instructions which represent various logic within the processor. When read by a machine, the instructions may cause the machine to fabricate the logic to perform the techniques described herein. Such representations, known as “IP cores,” are reusable units of logic for an integrated circuit that may be stored on a tangible, machine-readable medium as a hardware model that describes the structure of the integrated circuit. The hardware model may be supplied to various customers or manufacturing facilities, which load the hardware model on fabrication machines that manufacture the integrated circuit. The integrated circuit may be fabricated such that the circuit performs operations described in association with any of the embodiments described herein.

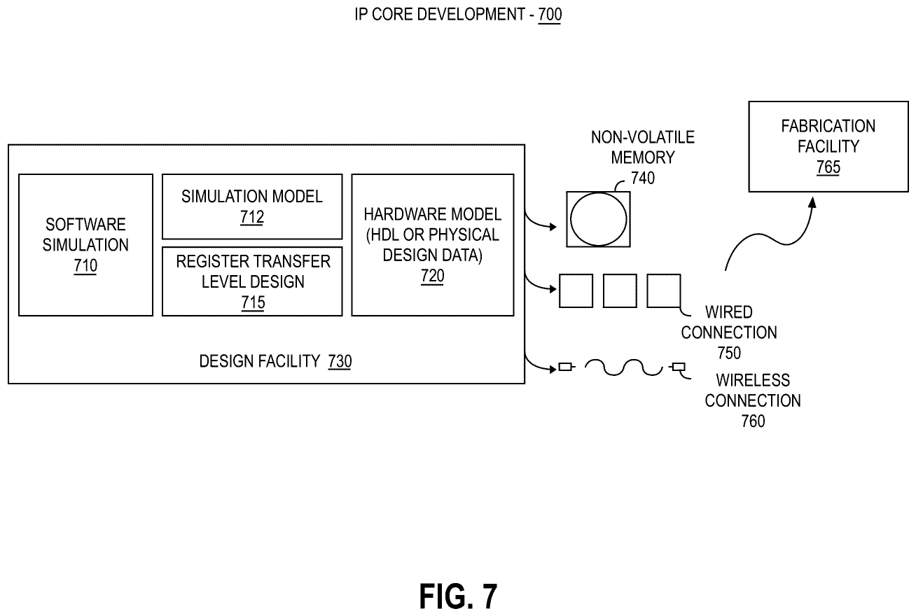

FIG. 7 is a block diagram illustrating an IP core development system 700. The IP core development system 700 may be used to manufacture an integrated circuit to perform operations of fabric and datacenter components described herein. The IP core development system 700 may be used to generate modular, re-usable designs that can be incorporated into a larger design or used to construct an entire integrated circuit (e.g., an SOC integrated circuit). A design facility 730 can generate a software simulation 710 of an IP core design in a high-level programming language (e.g., C/C++). The software simulation 710 can be used to design, test, and verify the behavior of the IP core using a simulation model 712. The simulation model 712 may include functional, behavioral, and/or timing simulations. A register transfer level design (RTL design 715) can then be created or synthesized from the simulation model 712. The RTL design 715 is an abstraction of the behavior of the integrated circuit that models the flow of digital signals between hardware registers, including the associated logic performed using the modeled digital signals. In addition to an RTL design 715, lower-level designs at the logic level or transistor level may also be created, designed, or synthesized. Thus, the particular details of the initial design and simulation may vary.

The RTL design 715 or equivalent may be further synthesized by the design facility into a hardware model 720, which may be in a hardware description language (HDL), or some other representation of physical design data. The HDL may be further simulated or tested to verify the IP core design. The IP core design can be stored for delivery to a fabrication facility 765 using non-volatile memory 740 (e.g., hard disk, flash memory, or any non-volatile storage medium). The fabrication facility 765 may be a 3^{rd} party fabrication facility. Alternatively, the IP core design may be transmitted (e.g., via the Internet) over a wired connection 750 or wireless connection 760. The fabrication facility 765 may then fabricate an integrated circuit that is based at least in part on the IP core design. The fabricated integrated circuit can be configured to perform operations in accordance with at least one embodiment described herein.

### Management of Data for Pipeline Operation

The processing of artificial intelligence (AI) workloads and usages are heavily dependent on network capabilities, and limitations in such network capabilities can greatly increase latencies. A particular drawback in network infrastructure is the handling of last packets in processing. In operation, AI software is generally required to wait for a last packet before the software can commence processing.

Improvements in network data propagation and processing can directly benefit the performance of AI deployments. Specifically, implementation of concurrent data processing and data movement would greatly benefit AI deployment pipelines. The challenge with concurrent data processing and data movement in current AI network infrastructures is that there are generally no capabilities for an infrastructure to handle “holes” in the data, e.g., data elements that are unavailable at any time because of, for example, latencies in transmission, slower processing related to such data elements, and other reasons. Current approaches involve waiting for all data to arrive before performing any processing on the data for AI applications. To minimize data movement delays, GPUs may provide fast proprietary interconnects or other improvements in device performance. However, while this technology can reduce the impact for AI and other processing when there are data unavailability issues, this does not address the underlying problems related to such data.

In some embodiments, an apparatus, system, or process facilitates concurrent processing and data movement for network pipelines, such as a pipeline for AI processing. In order to facilitate concurrent processing and data movement, an infrastructure provides awareness of contents of incoming data streams, and capabilities to address circumstances in which certain data elements are not available. In some embodiments, an apparatus, which may include an infrastructure processing unit (IPU), data processing unit (DPU), or other hardware accelerator, includes a capability to track, analyze, and suitably augment incoming data streams to enable concurrent processing of data, thereby allowing for accelerating operation of a network pipelines.

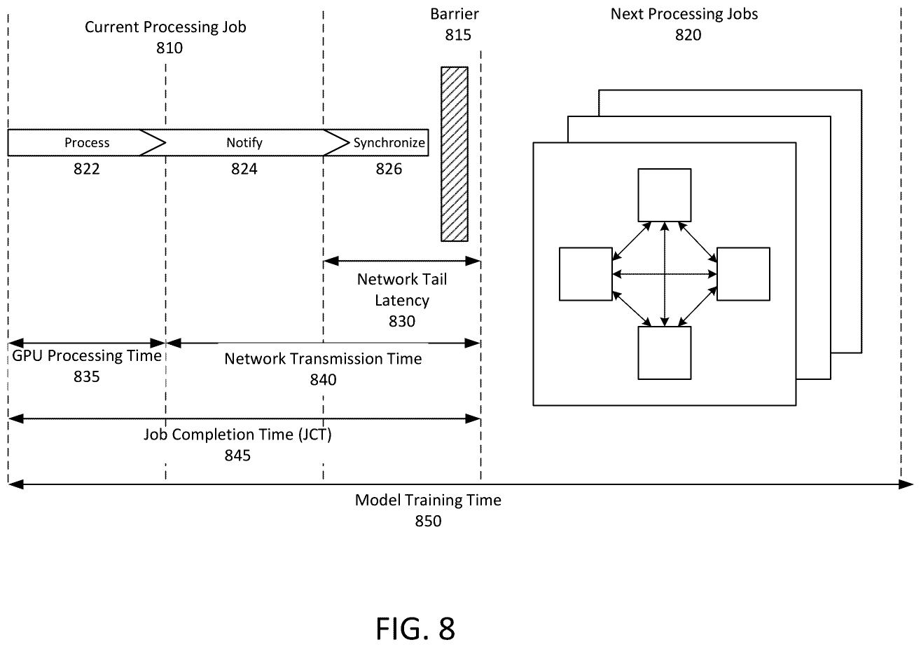

FIG. 8 is an illustration of network processing for a model. As illustrated in FIG. 8, a current processing job 810 is performed, to be followed by some number of next processing jobs 820. The processing of a current processing job 810 may be viewed as a process 822 relating to a GPU (or other processor) processing time 835, followed by providing for notifying re data results (notify 824) and synchronizing (synchronize 826) upon reaching a barrier 815. In general, a barrier refers to an element that requires any thread/process to stop at a point and not proceed until all other threads/processes reach this barrier. The notifying and synchronizing relate to a network transmission time 840, which will include a network tail latency 830. Network tail latency in general refers to the latency for a number of requests (generally a smaller number in comparison to the full set of requests) that require the greatest relative amount of time. For example, a small percentage of processing requests may have significantly greater latency than the other processing requests. The GPU processing time 835 and network transmission time 840 are together equal to the job completion time (JCT), after which will follow the next processing jobs 820. The overall time (job completion time 845 plus the time for the next processing jobs) is the full model training time 850 (or other full processing time). While the example illustrated in FIG. 8 regards model training, similar issues are present for other types of network processing, and embodiments described herein are not limited to this example.

The network tail latency 830 has a particularly significant effect on AI processing. Many AI workloads are distributed among multiple nodes in a network, and delays in receipt of any portion of the data can significantly impact the overall processing performance for AI. It is generally necessary to wait for arrival of all of the relevant data from the various nodes to commence following processing on the data, such as processing by AI software or other application. There are multiple aspects to possible delays in receipt of data on the network, including network latency, transmission time, job completion time, and model training time for AI use case. As a result, the required data often will not arrive at a same time, with certain data elements accounting for a large amount of the time required (e.g., the network tail latency).

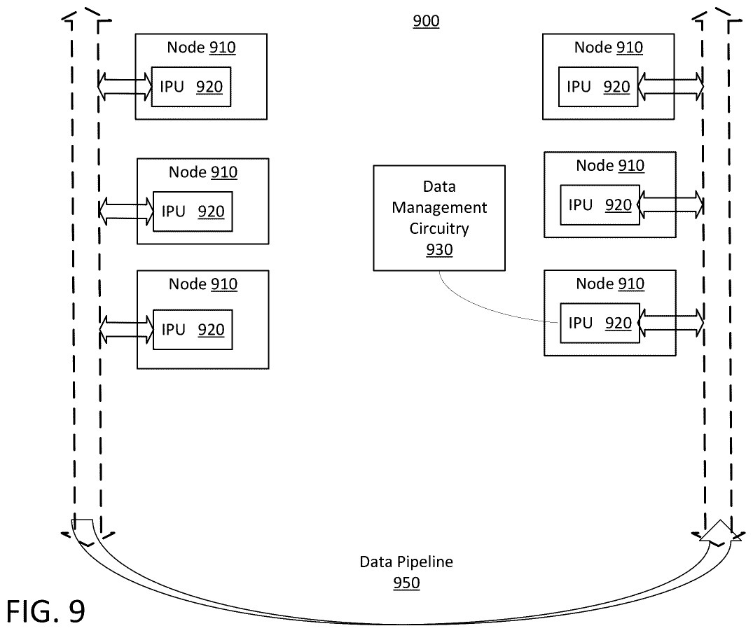

FIG. 9 is an illustration of last packet processing in an apparatus, according to some embodiments. As illustrated in FIG. 9, a system 900 may include multiple nodes 910 (which may be referred to as head nodes) that are engaged in processing for AI or other compute intensive, parallel processing. One or more of the nodes 910 includes an accelerator, such as the illustrated IPU 920, to support processing operations that is performed in the nodes 910. The system 900 may include a data pipeline 950 that is utilized in the transfer of data. However, the AI or other processing involves the transfer of multiple results via the data pipeline 950. In conventional processing, the processing results are needed to proceed in processing. However, one or more of the results may be delayed or missing.

In some embodiments, an apparatus, system, or process provides certain data management capabilities utilizing an IPU or other accelerator to improve processing infrastructures for pipeline operation through analysis and data modification, which capabilities may include:

(1) Capability to register and log alternative pathways from end users (such as reduced precision or reduced sampled execution tolerance for a set of models), and make decisions to use these alternatives based on incoming network data. For example, depending on a particular application, it may be acceptable to reduce precision or sampling to allow for improved processing time.

(2) Capability to analyze incoming data streams, and make decisions to implement AI based data shaping, which may include extrapolation or interpolation based on known data factors. For example, AI may have the ability to shape data that is missing, using reasonable extrapolation or interpolation.

(3) Capability to learn and store in memory information regarding correlation between shaped or extrapolated/interpolated input and model accuracy/output for a given model ID to compensate for data that has not yet arrived.

(4) Capability to decide, and instruct the infrastructure to leverage approximated computing techniques when suitable for a given problem. The approximated computing techniques may include, but are not limited to, reduction in precision or sampling in computing, allowing for reduced processing times.

Numerous different capabilities for data modification in network operation may be implemented in an apparatus. In an example, a network pipeline includes capabilities to operate on reduced precision or sampling, and maintains a running tracker of approximation and estimator of approximation error while determining how to handle holes in data for the pipeline. In another example, an apparatus include a capability for handling of smaller TCP (Transmission Control Protocol) Packets. In some embodiments, delayed or missing data can be identified and modified with the provision of replacement data (where replacement data may be “dummy” data or other data to substitute for original data) for faster processing. In some cases, if the data arrives late, the replacement data may be overwritten with the received data.

It is noted that data integrity mechanisms such as a CRC (Cyclic Redundancy Check) or checksum generally require a complete dataset to arrive before the data integrity can be verified. However, while the data is arriving there are, for example, several real-time signal-to-noise-ratio indicators from the interconnect physical layer that that can be used to estimate the likelihood of data integrity issues. In some embodiments, telemetry from these interconnect physical layers can be used to estimate the likelihood of a data integrity issue. Based on this estimate and the application's specified sensitivity to data corruption, the data can be forwarded for processing in a cut-through manner, or held for full integrity verification before forwarding.

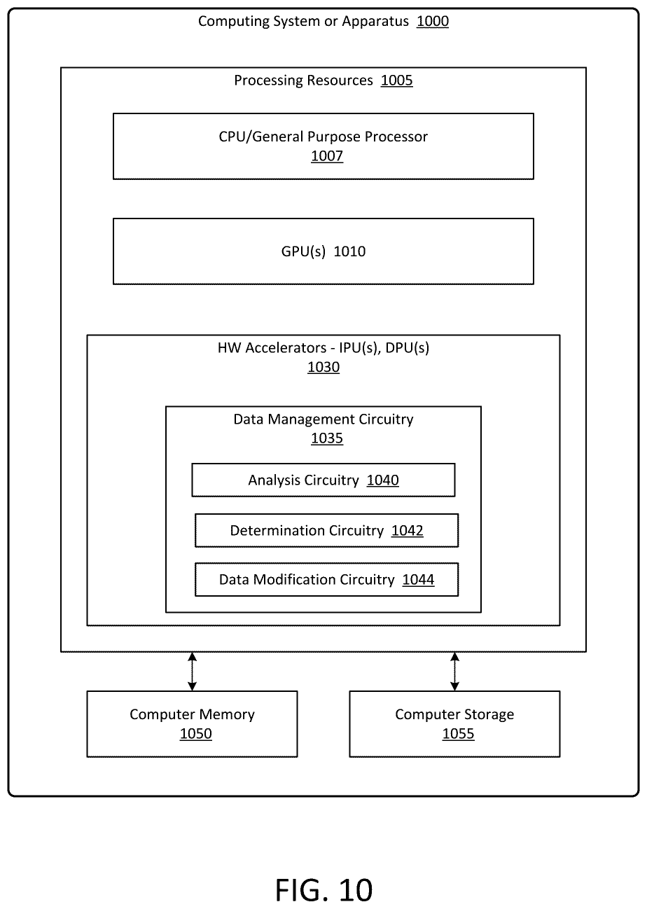

FIG. 10 is an illustration of a computing system or apparatus including support for concurrent processing and data movement in a data pipeline, according to some embodiments. In some embodiments, a computing system or apparatus 1000 includes hardware components to support data modifications in processing, allowing for handling of data that is delayed or missing in transmission. As illustrated in FIG. 10, the computing system or apparatus 1000, which may include processing system 100 illustrated in FIG. 1, includes processing resources 1005, wherein the processing resources 1005 may include one or more central processing units (CPUs) or other general purpose processors 1007, multiple graphical processing units (GPUs) 1010, which may be configured in sets or clusters for processing, and one or more hardware accelerators, which may include infrastructure processing units (IPUs), data processing units (DPUs), SmartNICs (Smart Network Interface Cards), and other apparatuses. As used herein, accelerator refers to an apparatus to accelerate processing operation by one or more processors. The one or more processing resources 1005 may include, but are not limited to, elements as illustrated for processors in FIGS. 1 to 7. The computing system or apparatus 1000 may further include computer memory 1050, such as high-bandwidth memory (HBM), and computer storage 1055, such as a solid-state drive (SSD), hard disk drive (HDD), or other storage technology, to store data for processing.

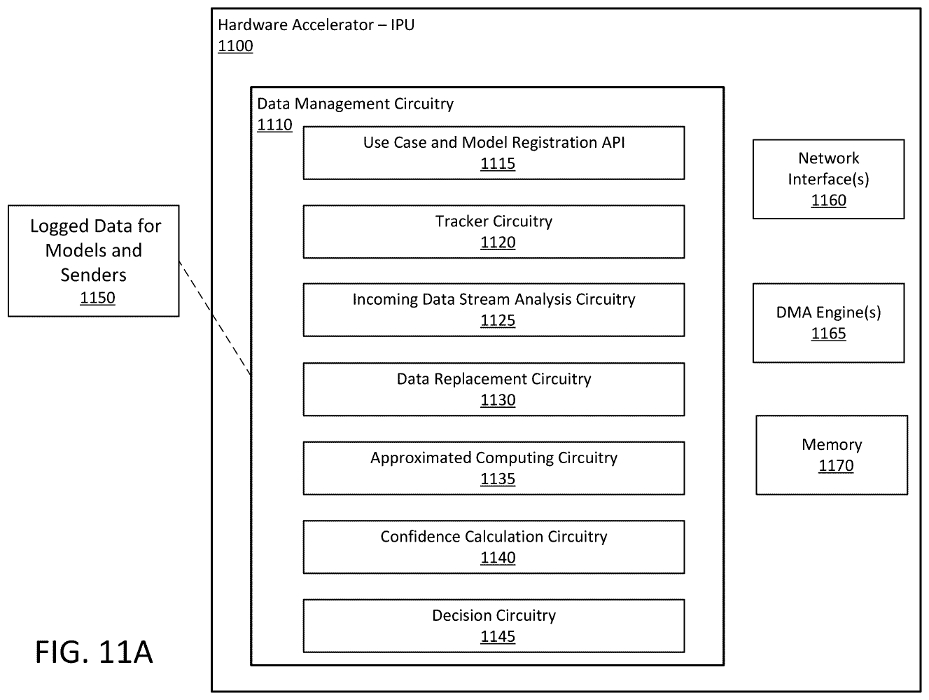

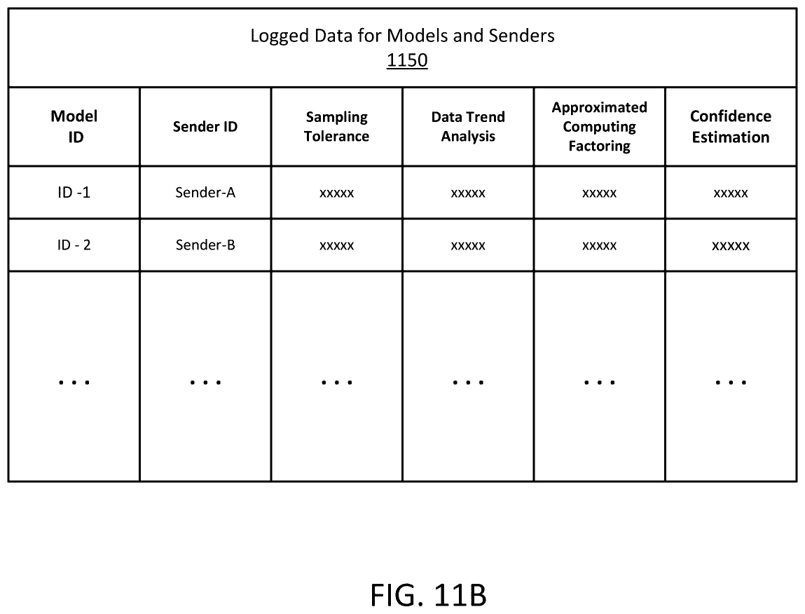

In some embodiments, the one or more hardware accelerators 1030 include, but are not limited to, data management circuitry 1035 to support concurrent processing and data movement for pipeline operation. The data management circuitry 1035 includes analysis circuitry 1040 to analyze a plurality of data elements transferred on the network to identify data elements that are delayed or missing in transmission on the network, determination circuitry 1042 to determine one or more responses to delayed or missing data on the network, and data modification circuitry 1044 to implement one or more data modifications for delayed or missing data on the network, wherein the data modification may include one or more of multiple different types of data modifications. In some embodiments, the data modification circuitry includes circuitry to provide replacement data for the delayed or missing data on the network. Additional details regarding the data management circuitry 1035 may be illustrated in FIG. 11A.

FIG. 11A is an illustration of a hardware accelerator including circuitry for concurrent processing and data movement for pipeline operation, according to some embodiments. In some embodiments, a hardware accelerator 1100 (which may include an IPU, DPU, SmartNIC, or other accelerator) includes data management circuitry 1110 to enable concurrent processing and data movement in a data pipeline, where the pipeline may include AI data transmission.

In some embodiments, the data management circuitry 1110 of the hardware accelerator 1100 includes one or more of the following mechanisms:

Use Case and Model Registration API Circuitry 1115—Use case and model registration API circuitry 1115 provides an API (Application Programming Interface) for AI usages and models to be registered with the hardware accelerator 1100. The API may include registration of one or more options that may be approved by a user for implementation in circumstances in which there is delayed or missing data in an incoming data stream. For example, there may be a set of one or more models registered with multiple allowed dataset sampling settings. In such a scenario, the API provides the user ability to register this information for possible implementation for data management for the one or more models in circumstances in which there is delayed or missing data in an operation. However, embodiments are not limited to this example, and API may include other programming selections.

Tracking Circuitry 1120—Tracking circuitry 1120 includes capability for tracking incoming data, including information registered by the API 1115. The tracking circuitry may include tracking data modifications based on user feedback and real time analysis. For example, a model that was not explicitly registered may be found to provide comparable accuracies with greatly reduced sampling, and this information may be tracked by the tracking circuitry 1120.

Incoming Data Stream Analysis Circuitry 1125—Incoming data stream analysis circuitry 1125 operates to analyze incoming data streams, including analysis related to delayed or missing data. The analysis circuitry 1125 may, for example, include a circular buffer that includes capability to log and analyze incoming data packets on receipt of a trigger by the infrastructure. In some embodiments, any trends that are observed from the incoming data may promoted to storage (long term memory), such as in memory 1170, and tracked against respective model ID and sender ID.

Data Replacement Circuitry 1130—Data replacement circuitry 1130 provides for replacement of delayed or missing data to allow for processing to proceed. Data replacement may include data shaping and extrapolation or interpolation in response to delayed or missing data. Given that generative AI (genAI) and AI have strong capabilities to augment missing information in data, the data replacement circuitry 1130 may be utilized to provide data shaping and extrapolation or interpolation in use cases where a set of minimum data is required to proceed forward in AI processing. Data replacement may further include, for example, generating random or pseudo-random data, duplicating previously received data or previously received data within certain bounds, modifying or adjusting previous data (e.g., using fuzzed data) to generate replacement data, generating an average or other value based on previously received data, inserting expected or predicted data values, or inserting zero or other constant data.

Approximated Computing Circuitry 1135—In some embodiments, approximated computing may be implemented by approximated computing circuitry 1135. Approximated computing involves implementation of one or more modifications in the normal computation to allow for increased speed in operation. The one or more modifications may include, but are not limited to, reduced precision operations (e.g., reducing the precision from a first precision to a second lower precision), reduced sampling in an operation, or other computing approximations. In some embodiments, the approximated computing may be implemented when required to address delayed or missing data in the incoming data stream. The approximated computing circuitry 1135 may operate to confirm options that registered by a user via the API 1125, and operate to trigger one or more options when this is allowed by decision circuitry 1145.

Decision Circuitry 1145—Decision circuitry 1145 is to determine one or more responses to delayed or missing data on the network. The determination may be based at least in part on analysis provided by incoming data stream analysis circuitry 1125 and registration of one or more options that may be approved by a user for implementation in circumstances in which there is delayed or missing data in an incoming data stream utilizing the use case and model registration API circuitry 1115. A decision may include determining whether to pause to wait for all data to arrive, or deciding to implement one or more data modifications. A decision to pause and wait for data may be made upon determining one or more factors for not implementing data modification for delayed or missing data.

Confidence Calculation Circuitry 1140—Confidence calculation circuitry 1140 provides for calculation of a confidence in a given decision for data management. The calculation of the confidence may be based on one or more factors, including user specified tolerance to reduced accuracies, the infrastructure can make a decision to pause and wait for more network data, or proceed forward.

The hardware accelerator 1100 may further include memory 1170. The memory 1170 be long term memory, such as nonvolatile memory, for storage of data, including data related to AI operation. The long term memory may be utilized by the hardware accelerator 1100 to store data trends that can be leveraged for data shaping or sampling. This information may be tracked for a given set of models or against a set of data source/sender IDs.

The accelerator 1100 may further comprise additional elements, which may include, but are not limited to, one or more network interfaces 1160 for connection on a network, and one or more direct memory access (DMA) engines 1165 to transfer data on the network.

FIG. 11B is an illustration of logged data for models and senders generated by a hardware accelerator, according to some embodiments. In some embodiments, a hardware accelerator, such as the hardware accelerator 1100 illustrated in FIG. 11A, is to log data 1150 associated with pipeline operation in connection with data management for delayed or missing data.

The logged data 1150 may include a model ID, representing one of multiple different models that may be subject of processing in a current processing job. Also included may be a sender ID for a particular sender in an operation; a sampling tolerance for operation; a data trend analysis for a data stream; approximated computer factoring related to one more computing approximations that may be implemented; and a confidence estimation for data modification decisions in operation.

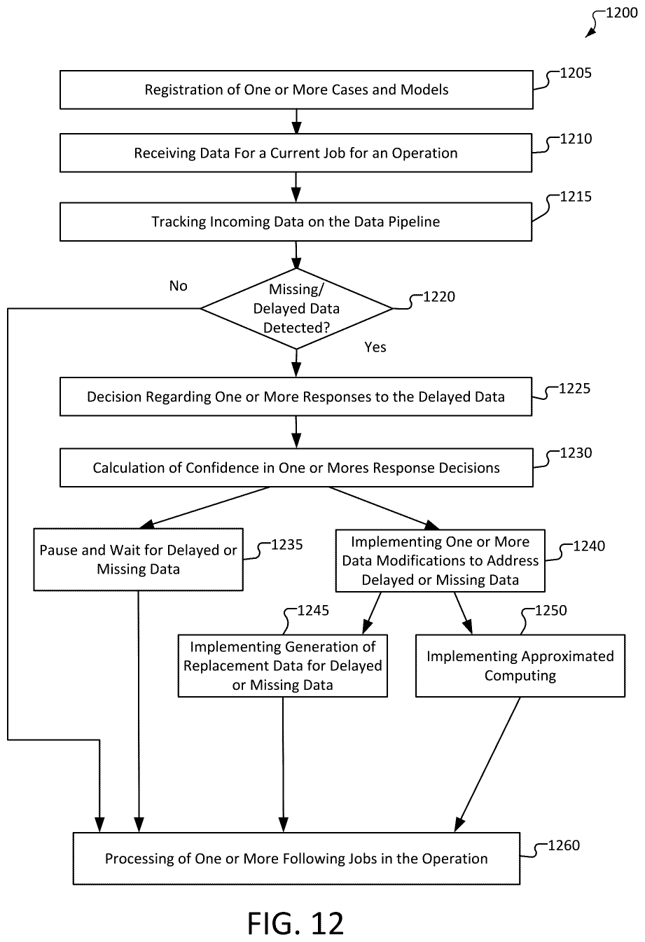

FIG. 12 is a flowchart to illustrate a process for data management in pipeline operation, according to some embodiments. In some embodiments, a process 1200 provides for data management in a data pipeline to address instances of delayed or missing data for a current processing job. A current processing job 810 may be as illustrated in FIG. 8, where the current processing job 810 may be followed by one or more next processing jobs 820. In some embodiments, the process 1200 may include registration of one or more use cases and models as provided by a user 1205, which may include registration utilizing an API to input data. The one or more uses cases and models may relate to s information for possible implementation for data management for the one or more models in circumstances in which there is delayed or missing data in an operation.

The process 1200 may proceed with receiving data for a current processing job for an operation 1210. The operation may include, but is not limited to, training of a model in an AI or machine learning process. In the operation, there are multiple data elements that are generally required to complete the current processing job, but one or more data elements may be delayed or missing, resulting in latency in completing the job, and proceeding to any following jobs. The delay may relate to a network tail latency in which a minority percentage of the number of data elements are the cause of the majority of the amount of latency,

In some embodiments, the process 1200 includes tracking incoming data on the pipeline 1215, which may include tracking data based at least in part on information registered by the API. The tracking may include tracking data modifications based on user feedback and real time analysis. The process 1200 may proceed analysis of the received data, including analysis related to delayed or missing data.

If there is no missing or delayed data detected 1220, and the process may proceed to processing of one or more following jobs in the operation 1260. In some embodiments, upon determining that there is delayed or missing data for the current processing job 1220, the process 1200 includes making a decision regarding one or more responses to be implemented in response to delayed or missing data on the network 1225. The determination may be made based at least in part on a calculation of a confidence in one or more response decisions 1230.

A decision regarding one or more responses to the delayed or missing data may include to pause and wait for the delayed or missing data 1235, and thus allowing for the data to arrive, with the inherent latency involved. A decision to pause and wait may be made upon determining one or more factors for not implementing data modification for delayed or missing data. The decision to pause and wait may be implemented when, for example, the anticipated delay is not significant, when there is no acceptable mitigating processing action based on the current conditions, or if there is a low confidence that identified mitigating actions will result in a satisfactory result.

A decision regarding one or more responses to the delayed or missing data may further include implementing one or more data modifications to address the delayed or missing data 1240. The implementation of data modifications may include generating replacement data for the delayed or missing data and utilizing such replacement data in the processing 1245. In an example, the replacement data may be data generated by data shaping or extrapolation or interpolation using prior knowledge for the data. Replacement data may further include, for example, random or pseudo-random data, previously received data that has been duplicated or duplicated within certain bounds, modified or adjusted previous data (e.g., using fuzzed data), an average or other generated value based on previously received data, expected or predicted data values, or zero or other constant data. The replacement data may be placeholder data that has not been derived for the operation, but that may be utilized for a least a portion of the processing.

The implementation of data modification may further include implementation of approximated computing 1250 to enable completion of the operation more quickly. The approximated computing may include, but is not limited to, implementation of reduced precision operations (e.g., reducing the precision from a first precision to a second lower precision), reduced sampling in an operation, or other computing approximations.

Following the determined action for the delayed or missing data (such as 1235, 1240, or 1245), the process 1200 may proceed with processing of one or more following jobs in the operation 1260.

The following Examples pertain to certain embodiments:

In Example 1, an apparatus includes one or more network interfaces; and a circuitry for management of data transfer for a network, wherein the circuitry for management of data transfer includes at least circuitry to analyze a plurality of data elements transferred on the network to identify data elements that are delayed or missing in transmission on the network, circuitry to determine one or more responses to delayed or missing data on the network, and circuitry to implement one or more data modifications for delayed or missing data on the network, including circuitry to provide replacement data for the delayed or missing data on the network.

In Example 2, for the apparatus of Example 1, the circuitry to provide replacement data includes circuitry to perform data shaping to generate data to replace delayed or missing data on the network.

In Example 3, for the apparatus of Example 1 or 2, the circuitry to implement one or more data modifications includes circuitry to provide approximated computing in response to delayed or missing data on the network.

In Example 4, for the apparatus of any of Examples 1 to 3, the approximated computing includes one or more of a reduced precision in processing or a reduced sampling in processing.

In Example 5, for the apparatus of any of Examples 1 to 4, the circuitry for management of data includes circuitry for calculating a confidence in the one or more responses to delayed or missing data on the network.

In Example 6, for the apparatus of any of Examples 1 to 5, the circuitry for management of data further provides for pausing and waiting for delayed or missing data upon determining one or more factors for not implementing data modification for delayed or missing data.

In Example 7, for the apparatus of any of Examples 1 to 6, the circuitry for management of data includes circuitry for an application processing interface (API), wherein the API includes registration of models for processing.

In Example 8, for the apparatus of any of Examples 1 to 7, the apparatus comprises an infrastructure processing unit (IPU).

In Example 9, a system includes a memory to store data for processing; a plurality of processors including a plurality of graphical processing units (GPUs); and one or more hardware accelerators including circuitry for management of data transfer for a network, wherein the circuitry for management of data transfer includes at least circuitry to analyze a plurality of data elements transferred on the network to identify data elements that are delayed or missing in transmission on the network, circuitry to determine one or more responses for delayed or missing data on the network, and circuitry to implement one or more data modifications for delayed or missing data on the network, including circuitry to provide replacement data for the delayed or missing data on the network.

In Example 10, for the system of Example 9, the circuitry to provide replacement data includes circuitry to perform data shaping to generate data to replace delayed or missing data on the network.

In Example 11, for the system of Examples 9 or 10, the circuitry to implement one or more data modifications includes circuitry to provide approximated computing in response to delayed or missing data on the network.

In Example 12, for the system of any of Examples 9 to 11, the approximated computing includes one or more of a reduced precision in processing or a reduced sampling in processing.

In Example 13, for the system of any of Examples 9 to 12, the circuitry for management of data includes circuitry for calculating a confidence in the one or more responses to delayed or missing data on the network.

In Example 14, for the system of any of Examples 9 to 13, the circuitry for management of data further provides for pausing and waiting for delayed or missing data upon determining one or more factors for not implementing data modification for delayed or missing data.

In Example 15, a method includes receiving a plurality of data elements transferred on a network from one or more sources; analyzing the plurality of data elements transferred on the network to identify data elements that are delayed or missing in transmission, determining one or more responses to the one or more data elements that are delayed or missing in transmission, and implementing one or more data modifications for delayed or missing data, where the data modifications include providing replacement data for the delayed or missing data on the network.

In Example 16, for the method of Example 15, providing replacement data includes performing data shaping to generate data to replace delayed or missing data on the network.

In Example 17, for the method of Example 15 or 16, implementing one or more data modifications includes providing approximated computing in response to delayed or missing data on the network.

In Example 18, for the method of any of Examples 15 to 17, the approximated computing includes one or more of a reduced precision in processing or a reduced sampling in processing.

In Example 19, for the method of any of Examples 15 to 18, the method further includes calculating a confidence in the one or more responses to delayed or missing data on the network.

In Example 20, for the method of any of Examples 15 to 19, the method further includes pausing and waiting for delayed or missing data upon determining one or more factors for not implementing data modification for delayed or missing data.

In Example 21, one or more non-transitory computer-readable storage mediums having stored thereon executable computer program instructions that, when executed by one or more processors, cause the one or more processors to perform operations comprising receiving a plurality of data elements transferred on a network from one or more sources; analyzing the plurality of data elements transferred on the network to identify data elements that are delayed or missing in transmission, determining one or more responses to the one or more data elements that are delayed or missing in transmission, and implementing one or more data modifications for delayed or missing data, where the data modifications include providing replacement data for the delayed or missing data on the network.

In Example 22, for the storage medium of Example 21, providing replacement data includes performing data shaping to generate data to replace delayed or missing data on the network.

In Example 23, for the storage mediums of Examples 21 or 22, implementing one or more data modifications includes providing approximated computing in response to delayed or missing data on the network.

In Example 24, for the storage mediums of any of Examples 21 to 23, the approximated computing includes one or more of a reduced precision in processing or a reduced sampling in processing.

In Example 25, for the storage mediums of any of Examples 21 to 24, the instructions further include instructions that, when executed by one or more processors, cause the one or more processors to perform operations comprising calculating a confidence in the one or more responses to delayed or missing data on the network.

In Example 26, for the storage mediums of any of Examples 21 to 25, the instructions further include instructions that, when executed by one or more processors, cause the one or more processors to perform operations comprising pausing and waiting for delayed or missing data upon determining one or more factors for not implementing data modification for delayed or missing data.

In Example 27, an apparatus includes means for receiving a plurality of data elements transferred on a network from one or more sources; means for analyzing the plurality of data elements transferred on the network to identify data elements that are delayed or missing in transmission, means for determining one or more responses to the one or more data elements that are delayed or missing in transmission, and means for implementing one or more data modifications for delayed or missing data, where the data modifications include providing replacement data for the delayed or missing data on the network.

In Example 28, for the apparatus of Example 27, providing replacement data includes performing data shaping to generate data to replace delayed or missing data on the network.

In Example 29, for the apparatus of Example 27 or 28, implementing one or more data modifications includes providing approximated computing in response to delayed or missing data on the network.

In Example 30, for the apparatus of any of Examples 27 to 29, the approximated computing includes one or more of a reduced precision in processing or a reduced sampling in processing.

In Example 31, for the apparatus of any of Examples 27 to 30, the apparatus further includes means for calculating a confidence in the one or more responses to delayed or missing data on the network.

In Example 32, for the apparatus of any of Examples 27 to 31, the apparatus further includes means for pausing and waiting for delayed or missing data upon determining one or more factors for not implementing data modification for delayed or missing data.

While the description and illustration of embodiments provided herein describe specific components, persons of skill in the art will be aware that such components may be combined into fewer elements, or may be split into a greater number of components as required or convenient for a particular implementation. For example, the described component providing for sorting and buffering of inputs may be expressed as a first sorting component and a second buffering component.

In the description above, for the purposes of explanation, numerous specific details are set forth in order to provide a thorough understanding of the described embodiments. It will be apparent, however, to one skilled in the art that embodiments may be practiced without some of these specific details. In other instances, well-known structures and devices are shown in block diagram form. There may be intermediate structure between illustrated components. The components described or illustrated herein may have additional inputs or outputs that are not illustrated or described.

Various embodiments may include various processes. These processes may be performed by hardware components or may be embodied in computer program or machine-executable instructions, which may be used to cause a general-purpose or special-purpose processor or logic circuits programmed with the instructions to perform the processes. Alternatively, the processes may be performed by a combination of hardware and software.

Portions of various embodiments may be provided as a computer program product, which may include a computer-readable medium having stored thereon computer program instructions, which may be used to program a computer (or other electronic devices) for execution by one or more processors to perform a process according to certain embodiments. The computer-readable medium may include, but is not limited to, magnetic disks, optical disks, read-only memory (ROM), random access memory (RAM), erasable programmable read-only memory (EPROM), electrically-erasable programmable read-only memory (EEPROM), magnetic or optical cards, flash memory, or other type of computer-readable medium suitable for storing electronic instructions. Moreover, embodiments may also be downloaded as a computer program product, wherein the program may be transferred from a remote computer to a requesting computer.

Many of the methods are described in their most basic form, but processes can be added to or deleted from any of the methods and information can be added or subtracted from any of the described messages without departing from the basic scope of the present embodiments. It will be apparent to those skilled in the art that many further modifications and adaptations can be made. The particular embodiments are not provided to limit the concept but to illustrate it. The scope of the embodiments is not to be determined by the specific examples provided above but only by the claims below.

If it is said that an element “A” is coupled to or with element “B,” element A may be directly coupled to element B or be indirectly coupled through, for example, element C. When the specification or claims state that a component, feature, structure, process, or characteristic A “causes” a component, feature, structure, process, or characteristic B, it means that “A” is at least a partial cause of “B” but that there may also be at least one other component, feature, structure, process, or characteristic that assists in causing “B.” If the specification indicates that a component, feature, structure, process, or characteristic “may”, “might”, or “could” be included, that particular component, feature, structure, process, or characteristic is not required to be included. If the specification or claim refers to “a” or “an” element, this does not mean there is only one of the described elements.

An embodiment is an implementation or example. Reference in the specification to “an embodiment,” “one embodiment,” “some embodiments,” or “other embodiments” means that a particular feature, structure, or characteristic described in connection with the embodiments is included in at least some embodiments, but not necessarily all embodiments. The various appearances of “an embodiment,” “one embodiment,” or “some embodiments” are not necessarily all referring to the same embodiments. It should be appreciated that in the foregoing description of exemplary embodiments, various features are sometimes grouped together in a single embodiment, figure, or description thereof for the purpose of streamlining the disclosure and aiding in the understanding of one or more of the various novel aspects. This method of disclosure, however, is not to be interpreted as reflecting an intention that the claimed embodiments requires more features than are expressly recited in the claims. Rather, as the following claims reflect, novel aspects lie in less than all features of a single foregoing disclosed embodiment. Thus, the claims are hereby expressly incorporated into this description, with a claim standing on its own as a separate embodiment.

The foregoing description and drawings are to be regarded in an illustrative rather than a restrictive sense. Persons skilled in the art will understand that various modifications and changes may be made to the embodiments described herein without departing from the broader spirit and scope of the features set forth in the appended claims.

What is claimed is:

1. An apparatus comprising:
one or more network interfaces; and
a circuitry for management of data transfer for a network;
wherein the circuitry for management of data transfer includes at least:
circuitry to analyze a plurality of data elements transferred on the network to identify data elements that are delayed or missing in transmission on the network,
circuitry to determine one or more responses to delayed or missing data on the network, and
circuitry to implement one or more data modifications for delayed or missing data on the network, including circuitry to provide replacement data for the delayed or missing data on the network.

2. The apparatus of claim 1, wherein the circuitry to provide replacement data includes circuitry to perform data shaping to generate data to replace delayed or missing data on the network.

3. The apparatus of claim 1, wherein the circuitry to implement one or more data modifications includes circuitry to provide approximated computing in response to delayed or missing data on the network.

4. The apparatus of claim 3, wherein the approximated computing includes one or more of a reduced precision in processing or a reduced sampling in processing.

5. The apparatus of claim 1, wherein the circuitry for management of data includes circuitry for calculating a confidence in the one or more responses to delayed or missing data on the network.

6. The apparatus of claim 1, wherein the circuitry for management of data further provides for pausing and waiting for delayed or missing data upon determining one or more factors for not implementing data modification for delayed or missing data.

7. The apparatus of claim 1, wherein the circuitry for management of data includes circuitry for an application processing interface (API), wherein the API includes registration of models for processing.

8. The apparatus of claim 1, wherein the apparatus comprises an infrastructure processing unit (IPU).

9. A system comprising:
a memory to store data for processing;
a plurality of processors including a plurality of graphical processing units (GPUs); and
one or more hardware accelerators including circuitry for management of data transfer for a network;
wherein the circuitry for management of data transfer includes at least:
circuitry to analyze a plurality of data elements transferred on the network to identify data elements that are delayed or missing in transmission on the network,
circuitry to determine one or more responses for delayed or missing data on the network, and
circuitry to implement one or more data modifications for delayed or missing data on the network, including circuitry to provide replacement data for the delayed or missing data on the network.

10. The system of claim 9, wherein the circuitry to provide replacement data includes circuitry to perform data shaping to generate data to replace delayed or missing data on the network.

11. The system of claim 9, wherein the circuitry to implement one or more data modifications includes circuitry to provide approximated computing in response to delayed or missing data on the network.

12. The system of claim 11, wherein the approximated computing includes one or more of a reduced precision in processing or a reduced sampling in processing.

13. The system of claim 9, wherein the circuitry for management of data includes circuitry for calculating a confidence in the one or more responses to delayed or missing data on the network.

14. The system of claim 9, wherein the circuitry for management of data further provides for pausing and waiting for delayed or missing data upon determining one or more factors for not implementing data modification for delayed or missing data.

15. A method comprising:
receiving a plurality of data elements transferred on a network from one or more sources;
analyzing the plurality of data elements transferred on the network to identify data elements that are delayed or missing in transmission,
determining one or more responses to the one or more data elements that are delayed or missing in transmission, and
implementing one or more data modifications for delayed or missing data, where the data modifications include providing replacement data for the delayed or missing data on the network.

16. The method of claim 15, wherein providing replacement data includes performing data shaping to generate data to replace delayed or missing data on the network.

17. The method of claim 15, wherein implementing one or more data modifications includes providing approximated computing in response to delayed or missing data on the network.

18. The method of claim 17, wherein the approximated computing includes one or more of a reduced precision in processing or a reduced sampling in processing.

19. The method of claim 15, further comprising:
calculating a confidence in the one or more responses to delayed or missing data on the network.

20. The method of claim 15, further comprising:
pausing and waiting for delayed or missing data upon determining one or more factors for not implementing data modification for delayed or missing data.
